(19) United States
(12) Patent Application Publication
(10) Pub. No.: US 2026/0293148 A1
(43) Pub. Date: Sep. 24, 2026

(54) SEMICONDUCTOR DEVICE AND ELECTRONIC SYSTEM INCLUDING THE SAME

(71) Applicant: Samsung Electronics Co., Ltd., Suwon-si (KR)

(72) Inventor: Ki Joon Kim, Suwon-si, (KR)

(73) Assignee: Samsung Electronics Co., Ltd., Suwon-si (KR)

(21) Appl. No.: 19/358,367

(22) Filed: Oct. 14, 2025

(30) Foreign Application Priority Data
Mar. 20, 2025 (KR) 10-2025-0036176

(51) Int. Cl. H10B 51/30; H10B 51/20; H10B 51/40

(52) U.S. Cl. CPC H10B 51/30; H10B 51/20; H10B 51/40

(57) ABSTRACT

A semiconductor device according to embodiments includes a substrate, a gate stack structure including interlayer insulation layers and gate electrodes alternately stacked on the substrate, a channel structure including a channel layer extending in a first direction perpendicular to one surface of the substrate and connected to the substrate, the channel structure penetrating the gate stack structure and a multi-layered structure extending in the first direction and including a first layer located between the channel layer and the gate electrode, a second layer located between the first layer and the gate electrode, and a third layer located between the first layer and the second layer, wherein each of the first layer and the second layer includes a ferroelectric material or an antiferroelectric material, and the third layer includes at least one insulation layer.

### CROSS-REFERENCE TO RELATED APPLICATIONS

This present application claims priority to and the benefit under 35 U.S.C. § 119(a)-(d) of Korean Patent Application No. 10-2025-0036176, filed on Mar. 20, 2025, in the Korean Intellectual Property Office, the entire disclosure of which is incorporated herein by reference.

### BACKGROUND

The present disclosure relates to a semiconductor device and an electronic system including the same.

A semiconductor memory device may be broadly divided into volatile memory device and nonvolatile memory device. A volatile memory device is a type of memory device in which stored data is lost when power supply is interrupted. Examples of such volatile memory devices include a dynamic random access memory (DRAM) and a static random access memory (SRAM).

A non-volatile memory device is a type of memory device in which stored data is retained even when the power supply is interrupted. Examples of such non-volatile memory devices include a programmable read-only memory (PROM), an erasable programmable read-only memory (EPROM), an electrically erasable programmable read-only memory (EEPROM), and a flash memory device. In addition, in response to the trend toward high performance and low power consumption of semiconductor memory devices, next-generation non-volatile memory devices such as magnetic random access memory (MRAM), phase-change random access memory (PRAM), and ferroelectric random access memory (FeRAM) have been developed. As higher integration and enhanced performance of semiconductor devices are increasingly required, various studies using semiconductor devices having different characteristics have been conducted.

### SUMMARY

The embodiments are intended to provide a semiconductor device having an increased memory window and improved reliability, and an electronic system including the same.

A semiconductor device according to embodiments includes a substrate, a gate stack structure including interlayer insulation layers and gate electrodes alternately stacked on the substrate, a channel structure including a channel layer extending in a first direction perpendicular to one surface of the substrate and connected to the substrate, the channel structure penetrating the gate stack structure and a multi-layered structure extending in the first direction and including a first layer located between the channel layer and the gate electrode, a second layer located between the first layer and the gate electrode, and a third layer located between the first layer and the second layer, wherein each of the first layer and the second layer includes a ferroelectric material or an antiferroelectric material, and the third layer includes at least one insulation layer.

A semiconductor device according to embodiments includes a substrate, a gate stack structure including interlayer insulation layers and gate electrodes alternately stacked in a first direction perpendicular to a surface of the substrate, a channel structure including a core insulation layer extending in the first direction, and a channel layer located between the core insulation layer and the gate electrode and connected to the substrate, the channel structure penetrating the gate structure and a multi-layered structure extending in the first direction and including a first layer located between the channel layer and the gate electrode, a second layer located between the first layer and the gate electrode, and a third layer located between the first layer and the second layer, wherein each of the first layer and the second layer includes a ferroelectric material or an antiferroelectric material, wherein the third layer includes at least one insulation layer, and wherein the at least one insulation layer includes a charge storage layer containing an oxide and passivation layers containing a nitride and located on inner surface and outer surface of the charge storage layer.

An electronic system according to embodiments includes a main substrate, a semiconductor device on the main substrate and a controller electrically connected to the semiconductor device on the main substrate, wherein the semiconductor device includes a peripheral circuit area, a cell region including an input/output connection wiring electrically connected to the peripheral circuit area, and an input/output pad electrically connected to the input/output connection wiring extending into the cell region, wherein the cell region includes a substrate, a gate stack structure including interlayer insulation layers and gate electrodes alternately stacked on the substrate, a channel structure including a channel layer extending in a first direction perpendicular to a surface of the substrate and connected to the substrate, the channel structure penetrating the gate stack structure, and a multi-layered structure extending in the first direction and including a first layer located between the channel layer and the gate electrode, a second layer located between the first layer and the gate electrode, and a third layer located between the first layer and the second layer, wherein each of the first layer and the second layer includes a ferroelectric material or an antiferroelectric material, and the third layer includes at least one insulation layer.

A method for manufacturing a semiconductor device according to embodiments includes forming a gate stack structure including interlayer insulation layers and gate electrodes that are alternately stacked on a substrate, forming a channel hole penetrating the gate stack structure along a first direction perpendicular to one surface of the substrate, forming a multi-layered structure filling at least a portion of the channel hole, and forming a channel structure including a channel layer connected to the substrate inside the channel hole, wherein the forming the multi-layered structure includes, forming a second layer extending in the first direction inside the channel hole, forming a third layer on an inner surface of the second layer, and forming a first layer on an inner surface of the insulation layer, wherein each of the first layer and the second layer includes a ferroelectric material or an antiferroelectric material, and the third layer may include at least one insulation layer.

In the method of manufacturing the semiconductor device according to embodiments, the at least one insulation layer may include a charge storage layer and passivation layers located on both side surfaces of the charge storage layer.

In the method for manufacturing the semiconductor device according to embodiments, the charge storage layer may include an oxide, and the passivation layers may include a nitride.

In the method for manufacturing the semiconductor device according to embodiments, a dielectric constant of the oxide included in the charge storage layer may be smaller than or equal to a dielectric constant of the ferroelectric material included in the first layer and the second layer, or a dielectric constant of the antiferroelectric material.

In the method for manufacturing the semiconductor device according to embodiments, one of the first layer and the second layer may include a ferroelectric material, and the other may include an antiferroelectric material.

The method for manufacturing the semiconductor device according to embodiments may further include forming a gate insulation layer filling a portion of a channel hole, prior to forming the multi-layered structure.

The method for manufacturing the semiconductor device according to embodiments may further include a forming an additional charge storage layer on an inner surface of the gate insulation layer before forming the multi-layered structure.

According to embodiments, the memory window of the semiconductor device may be increased, and the reliability of the semiconductor device and an electronic system including the same may be improved.

### BRIEF DESCRIPTION OF THE DRAWINGS

FIG. 1 and FIG. 2 are cross-sectional views illustrating a semiconductor device according to embodiments.

FIG. 3 and FIG. 4 are cross-sectional views illustrating various examples of channel structures included in the semiconductor device illustrated in FIG. 1.

FIG. 5 is an enlarged cross-sectional view of region A of FIG. 2.

FIG. 6 illustrates a semiconductor device according to embodiments.

FIG. 7 illustrates a semiconductor device according to embodiments.

FIG. 8 illustrates a semiconductor device according to embodiments.

FIG. 9 illustrates a semiconductor device according to embodiments.

FIG. 10 illustrates a semiconductor device according to embodiments.

FIG. 11 to FIG. 17 are process cross-sectional views for explaining a method for manufacturing a semiconductor device according to embodiments.

FIG. 18 to FIG. 23 are process cross-sectional views for explaining a method for manufacturing a semiconductor device according to embodiments.

FIG. 24 is a partial cross-sectional view schematically illustrating a semiconductor device according to an additional embodiment.

FIG. 25 is a schematic diagram illustrating an electronic system including a semiconductor device according to embodiments.

FIG. 26 is a perspective view schematically illustrating an electronic system including a semiconductor device according to embodiments.

FIG. 27 and FIG. 28 are cross-sectional views schematically illustrating semiconductor packages according to embodiments, respectively.

### DETAILED DESCRIPTION

Hereinafter, various embodiments will be described in detail with reference to the attached drawings so that a person having ordinary skill in the art to which the present disclosure pertains may easily implement the disclosure. The present disclosure may be embodied in many different forms and is not limited to the embodiments described herein.

In order to clearly describe the present disclosure, portions irrelevant to the description are omitted, and throughout the specification, like or similar elements are denoted by the same reference numerals.

In addition, the sizes and thicknesses of components shown in the drawings are illustrated arbitrarily for the convenience of explanation, and thus the present disclosure is not limited to those illustrated. To clearly represent the various layers and areas in the drawing, the thickness is enlarged and shown. And in the drawing, for convenience of explanation, the thickness of some layers and areas is exaggerated.

In addition, when a layer, film, region, plate, or the like is described as being “on” or “over” another part, it is to be understood that this includes both cases where it is directly on the part and cases where another element may be interposed therebetween. Conversely, when a part is described as being “directly on” another part, it means that no other element is interposed therebetween. In addition, when a part is described as being “on” or “over” a reference part, it may be located above or below the reference part, and does not necessarily mean that it is positioned in a direction opposite to gravity.

Throughout the specification, when a part is described as “including” or “comprising” a component, it is to be understood that, unless expressly stated otherwise, the part may further include other components and does not exclude the presence of additional components.

Additionally, in the entire specification, the term “in plan view” refers to a view of the target portion as seen from above, and the term “in cross-sectional view” refers to a view of a cross-section of the target portion taken vertically and viewed from the side.

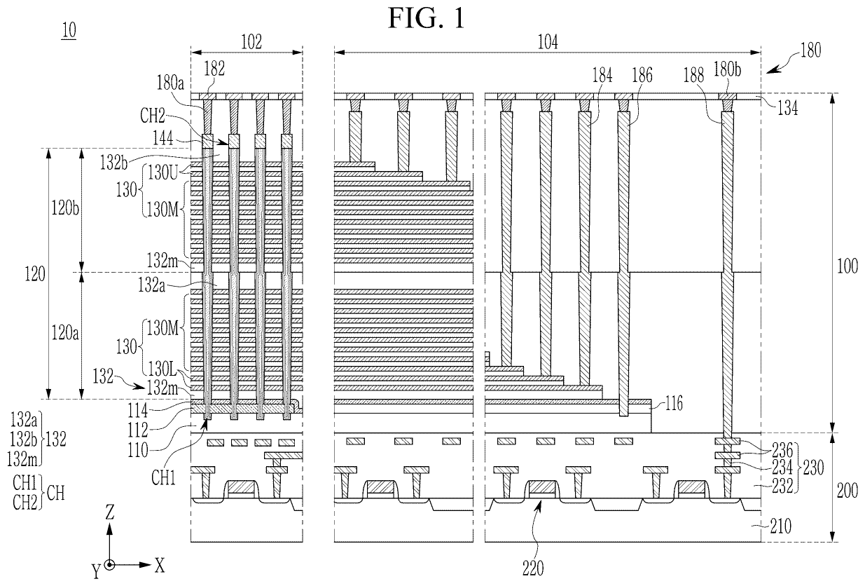

Hereinafter, a semiconductor device according to embodiments will be described with reference to FIG. 1 to FIG. 5.

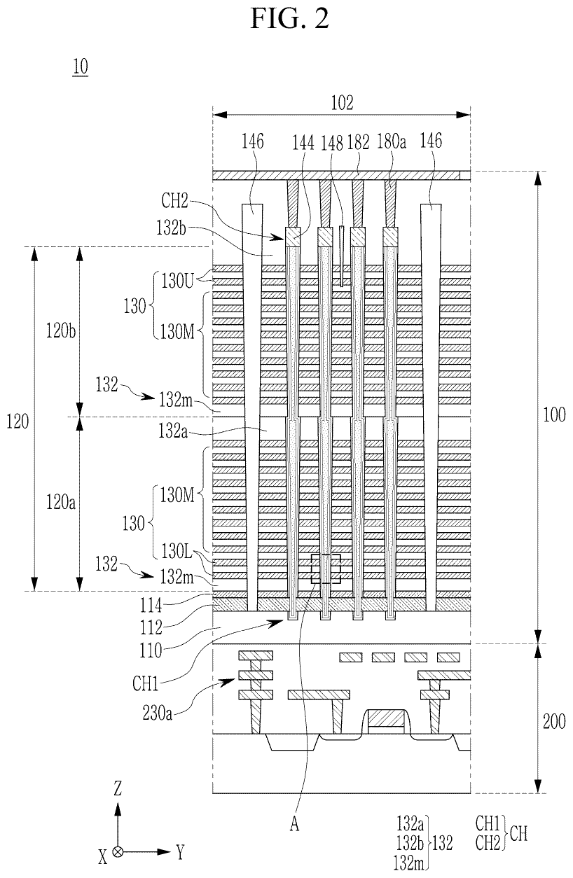

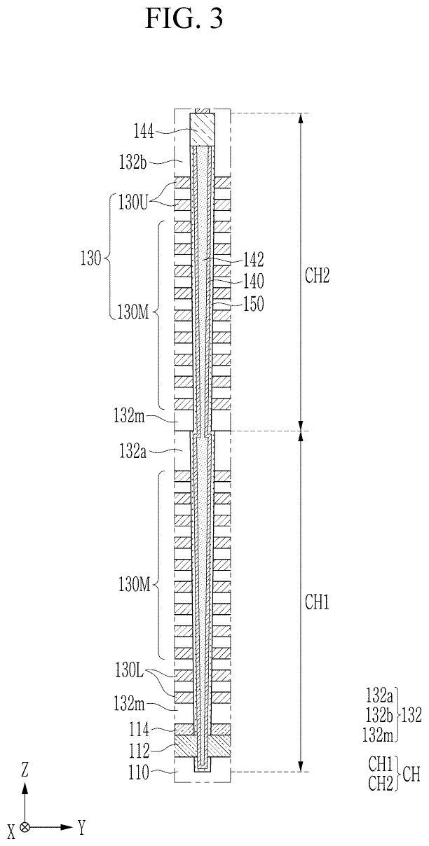

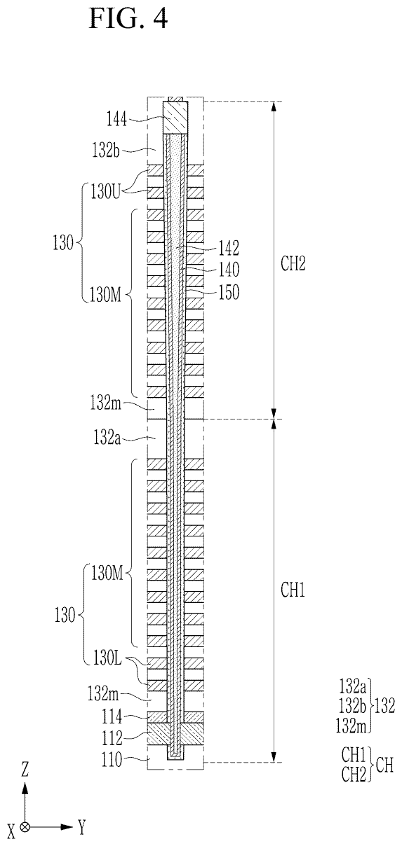

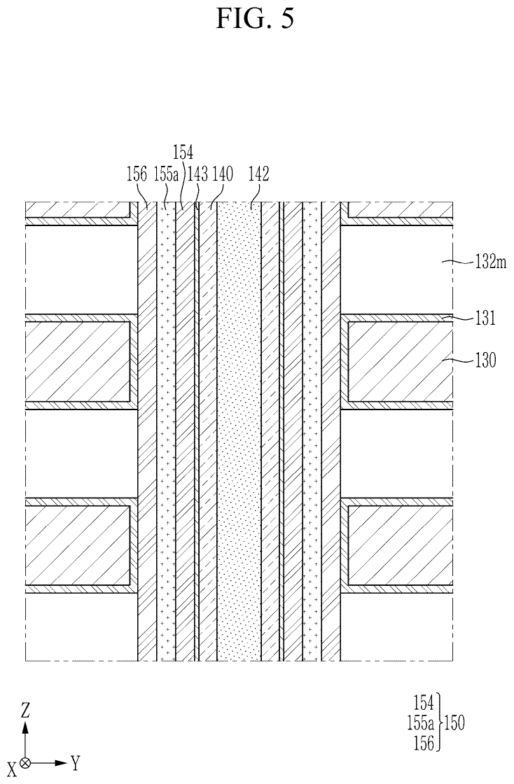

FIG. 1 and FIG. 2 are cross-sectional views illustrating a semiconductor device according to embodiments. FIG. 3 and FIG. 4 are cross-sectional views illustrating various examples of channel structures included in the semiconductor device illustrated in FIG. 1. FIG. 5 is an enlarged cross-sectional view of area A of FIG. 2.

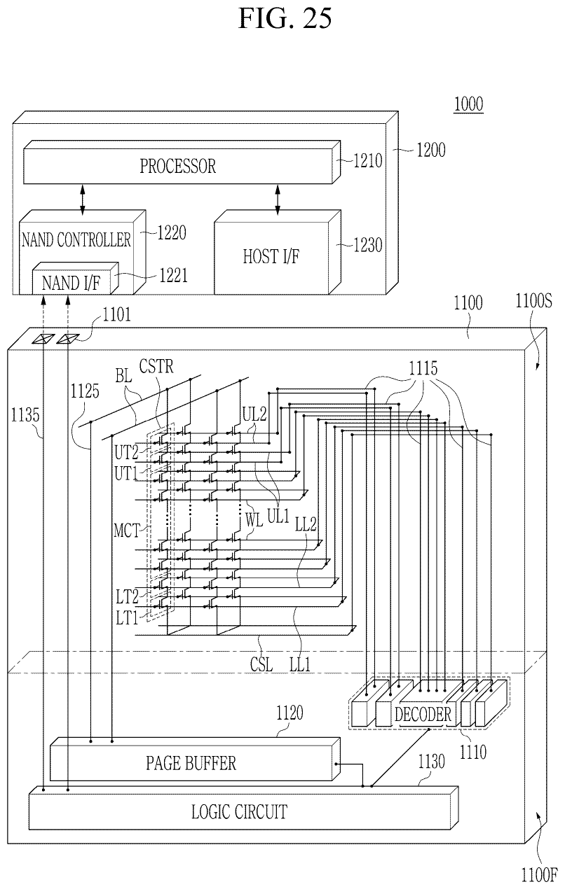

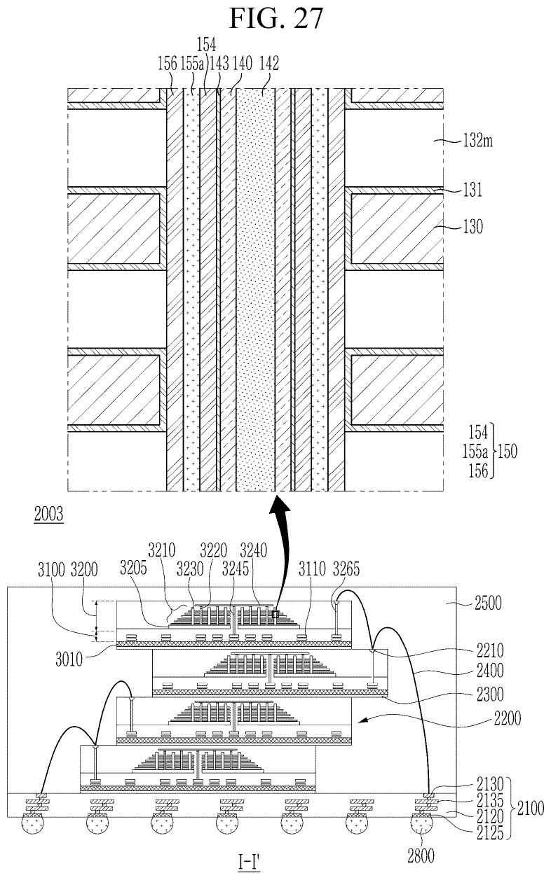

First, referring to FIG. 1 and FIG. 2, a semiconductor device 10 according to embodiments may include a cell region 100 in which a memory cell structure is provided, and a the circuit region 200 in which a peripheral circuit structure for controlling the operation of the memory cell structure is provided. For example, the circuit region 200 and the cell region 100 may be portions corresponding to the first structure 1100F and the second structure 1100S of the semiconductor device 1100 included in the electronic system 1000 illustrated in FIG. 25, respectively. Alternatively, the circuit region 200 and the cell region 100 may be portions corresponding to the first structure 3100 and the second structure 3200 of the semiconductor chip 2200 illustrated in FIG. 27, respectively.

In an exemplary embodiment, a cell region 100 may be positioned on a the circuit region 200. According to this, the area corresponding to the circuit region 200 does not need to be secured separately from the cell region 100, so the area of the semiconductor device 10 may be reduced. However, the embodiment is not limited thereto, and the circuit region 200 may be located next to the cell region 100. Many other changes are possible.

The cell region 100 may include a cell array region 102 and a contact region 104 positioned on a second substrate 110. The cell array region 102 may include a memory cell structure including a plurality of memory cells. The contact region 104 may include electrodes for electrically connecting the memory cells to other circuit elements (e.g., circuit elements 220 included in the circuit region 200 described below), or to external circuitry.

In embodiments, the cell array region 102 may include a gate stack structure 120 and a channel structure CH on a first surface (e.g., a front surface or upper surface) of a second substrate 110. In embodiments, the cell array region 102 may further include a multi-layered structure 150 positioned between the gate stack structure 120 and the channel structure CH and including a plurality of layers 154, 155a, 156.

The second substrate 110 may include a semiconductor material (e.g., polysilicon). For example, the second substrate 110 may include polysilicon doped with impurities. However, it is not limited thereto, and for example, the second substrate 110 may include a metal material or a metal silicide. A gate stack structure 120 in which a cell insulation layer 132 and a plurality of gate electrodes 130 are alternately stacked may be positioned on the second substrate 110.

In embodiments, the gate stack structure 120 may include a plurality of gate stack structures 120a, 120b that are sequentially stacked on a second substrate 110 and each of which includes alternately stacked cell insulation layers 132 and a plurality of gate electrodes 130. In this case, the number of stacked gate electrodes 130 may be increased, thereby allowing the number of memory cells to be increased with a stable structure. For example, the gate stack structure 120 may simplify the structure while increasing the data storage capacity by including the first and second gate stack structures 120a, 120b. However, the embodiment is not limited thereto, and the gate stack structure 120 may be composed of one gate stack structure or may include three or more gate stack structures.

In the gate stack structure 120, a plurality of gate electrodes 130 may include a lower gate electrode 130L, a memory cell gate electrode 130M, and an upper gate electrode 130U sequentially positioned from above the second substrate 110. The lower gate electrode 130L may be used as a gate electrode of a ground selection transistor, the memory cell gate electrode 130M may form a memory cell, and the upper gate electrode 130U may be used as a gate electrode of a string selection transistor. The number of memory cell gate electrodes 130M may be determined depending on the data storage capacity of the semiconductor device 10. According to embodiments, one or more lower gate electrodes 130L and upper gate electrodes 130U may be provided, and may have the same structure as or a different structure from the memory cell gate electrode 130M. And some of the plurality of gate electrodes 130, for example, the memory cell gate electrode 130M adjacent to the lower gate electrode 130L and the upper gate electrode 130U, may be dummy gate electrodes.

The semiconductor device according to the embodiment may further include a barrier layer 131 surrounding at least a portion of the gate electrode 130. The barrier layer 131 may be configured to prevent a material (e.g., a metal material) included in the channel layer 140 from diffusing to the outside of the gate electrode 130. Referring to FIG. 5, a barrier layer 131 may surround an upper surface, a lower surface, and side surfaces of the gate electrode 130 entirely. The barrier layer 131 may be located between the gate electrode 130 and the interlayer insulation layer 132m. The barrier layer 131 may also be located between the gate electrode 130 and the second layer 156 to be described later.

The barrier layer 131 may include a metal material. For example, the barrier layer 131 may include TiN, TaN, Ta, Ti, W, Co, and combinations thereof, but is not limited thereto.

The cell insulation layer 132 may include a plurality of interlayer insulation layers 132m located below the plurality of gate electrodes 130 or between adjacent gate electrodes 130 within the first and second gate stack structures 120a, 120b, and upper insulation layers 132a, 132b located on the top of the first and second gate stack structures 120a, 120b. For example, the upper insulation layer 132a, 132b may include a first upper insulation layer 132a positioned on the first gate stack structure 120a and a second upper insulation layer 132b positioned on the second gate stack structure 120b. At this time, the first upper insulation layer 132a may be an intermediate insulation layer positioned between the first gate stack structure 120a and the second gate stack structure 120b, and the second upper insulation layer 132b may be an uppermost insulation layer positioned at the top of the gate stack structure 120. The second upper insulation layer 132b may constitute a part or the entirety of a cell region insulation layer that is entirely located on the top of the cell region 100. In embodiments, the thicknesses of the plurality of cell insulation layers 132 may not all be the same. For example, the thickness of the upper insulation layer 132a, 132b may be greater than the thickness of the plurality of interlayer insulation layers 132m. However, the shape, structure, and the like of the cell insulation layer 132 may vary depending on the embodiment.

Referring to FIG. 1 to FIG. 4, the cell insulation layer 132 is illustrated as having a boundary between the first gate stack structure 120a and the second gate stack structure 120b in a contact region 104 to be described later, but the embodiment is not limited thereto. In the contact region 104, multiple insulation layers may have various stacking structures, and the embodiment is not limited thereto.

The plurality of gate electrodes 130 may include various conductive materials. For example, the plurality of gate electrodes 130 may include a metal material such as tungsten (W), copper (Cu), or aluminum (Al). As another example, the plurality of gate electrodes 130 may include polysilicon, a metal nitride (e.g., titanium nitride (TiN), tantalum nitride (TaN), etc.), or a combination thereof. The cell insulation layer 132 may include various insulating materials. For example, the cell insulation layer 132 may include silicon oxide, silicon nitride, silicon oxynitride, a low-k material having a lower dielectric constant than silicon oxide, or a combination thereof.

The channel structure CH may extend in a direction (for example, a third direction Z) that penetrates the gate stack structure 120 and intersects the second substrate 110. Referring further to FIG. 3 to FIG. 5, a channel structure CH of a semiconductor device according to embodiments may include a channel layer 140. The channel structure CH may further include a core insulation layers 142 inside the channel layer 140 and may further include a channel pad 144 positioned on the channel layer 140.

Each channel structure CH may form a respective memory cell string, and a plurality of channel structures CH may be spaced apart from each other and arranged in rows and columns in a plan view. For example, the plurality of channel structures CH may be arranged in various shapes, such as a lattice shape or a zigzag shape, on a plane.

In embodiments, the channel structure CH may have a columnar shape. For example, the channel structure CH may have inclined side surfaces such that, in a cross-sectional view, the width becomes narrower toward the second substrate 110 depending on the aspect ratio. However, the embodiment is not limited thereto, and the arrangement, structure, and shape of the channel structure CH may be variously modified.

A core insulation layer 142 is provided in the central region of the channel structure CH, and a channel layer 140 may be positioned while wrapping around the side wall of the core insulation layer 142. That is, the channel layer 140 may surround the core insulation layer 142. For example, the core insulation layer 142 may have a columnar shape (e.g., a cylindrical shape or a polygonal columnar shape), and the channel layer 140 may have a planar shape such as an annular shape. However, the embodiment is not limited thereto, and the core insulation layers 142 may not be provided and the channel layer 140 may have a columnar shape (for example, a cylindrical shape or a polygonal columnar shape).

The channel layer 140 may penetrate the first and second horizontal conductive layers 112, 114 to be described later. The channel layer 140 may be electrically connected to the first and second horizontal conductive layers 112, 114. For example, a portion of a side surface of the channel layer 140 may be in direct contact with and electrically connected to a side surface of the first horizontal conductive layer 112.

The channel layer 140 may include a semiconductor material, for example, polysilicon. The core insulation layer 142 may include various insulating materials. For example, the core insulation layers 142 may include silicon oxide, silicon nitride, silicon oxynitride, or a combination thereof. However, the materials of the channel layer 140 and the core insulation layer 142 are not limited thereto.

A channel insulation layer 143 may surround the channel layer 140. For example, the channel insulation layer 143 may extend in the third direction Z to surround the side surface of the channel layer 140. The channel insulation layer 143 may have a planar shape, such as an annular shape. In embodiments, the thickness of the channel insulation layer 143 in the second direction Y may be thinner than the thickness of the channel layer 140. In embodiments, the thickness of the channel insulation layer 143 along the second direction Y may be thinner than the thicknesses of the first layer 154, the second layer 156, and the charge storage layer 155a along the second direction Y to be described later. The channel insulation layer 143 may be, for example, a natural oxide film formed between the channel layer 140 and the first layer 154 in the process of forming the channel layer 140, but is not limited thereto. Unlike what is illustrated in FIG. 5, the semiconductor device according to embodiments may not include a channel insulation layer 143. In this case, the channel layer 140 may have one side surface that is in contact with the first layer 154 to be described later.

The channel insulation layer 143 may include an insulating material. For example, the channel insulation layer 143 may include at least one of silicon oxide (SiO₂), silicon oxynitride (SiON), aluminum oxynitride (AlON), hafnium oxynitride (HfON), aluminum oxide (Al₂O₃), and carbon (C)-doped silicon oxide (SiO₂). Alternatively, the channel insulation layer 143 may include a high-k material having a higher dielectric constant than silicon oxide (SiO₂). For example, the channel insulation layer 143 may include at least one of hafnium oxide (HfO₂), hafnium-zirconium oxide (HfXZr₁-XO₂), barium-titanium oxide (Ba₂TiO₃), and aluminum-scandium nitride (AlScN) doped with at least one of silicon (Si), aluminum (Al), yttrium Y, strontium (Sr), gadolinium (Gd), and lanthanum (La). The channel insulation layer 143 may be formed by stacking the plurality of layers including the insulating materials listed above, for example.

A multi-layered structures 150 may surround a channel structure CH. A multi-layered structures 150 may surround the channel insulation layer 143. The multi-layered structures 150 may extend in a direction parallel to the direction in which the channel structure CH extends. The multi-layered structures 150 may be extended along the third direction Z. In embodiments, the multi-layered structures 150 may include a first layer 154, a second layer 156, and a charge storage layer 155a positioned between the first layer 154 and the second layer 156. For example, the multi-layered structures 150 may include the first layer 154 surrounding the channel structure CH, the charge storage layer 155a surrounding the first layer 154, and the second layer 156 surrounding the charge storage layer 155a. In embodiments, the first layer 154, the charge storage layer 155a, and the second layer 156 may be sequentially stacked on the outer surface of the channel structure CH.

In embodiments, the thickness of each of the first layer 154, the charge storage layer 155a, and the second layer 156 along a direction perpendicular to the third direction Z (e.g., the radial direction of the channel structure CH) may be greater than or equal to about 0.1 nm, but is not limited thereto. In embodiments, the sum of the thicknesses of the channel structures CH of the first layer 154, the charge storage layer 155a, and the second layer 156 in the radial direction may be greater than or equal to about 0.3 nm and less than or equal to about 20 nm. However, it is not limited thereto, and the first layer 154, the charge storage layer 155a, and the second layer 156 may have various thicknesses depending on the type or location of the film.

The first layer 154 may surround the channel insulation layer 143. The first layer 154 may be located on the outer surface of the channel insulation layer 143. The first layer 154 may have one side surface in contact with the channel insulation layer 143. In embodiments, the semiconductor device 10 may not include a channel insulation layer 143. In this case, the one side surface of the first layer 154 may be in contact with the channel layer 140.

The first layer 154 may be extended in the third direction Z. In embodiments, the first layer 154 may overlap the gate electrode 130 and the channel structure CH in the radial direction. The first layer 154 may also overlap the interlayer insulation layer 132m in a radial direction of the channel structure CH. For example, a portion of the first layer 154 may overlap the gate electrode 130 and the channel structure CH in the radial direction, and a remaining portion of the first layer 154 may overlap the plurality of interlayer insulation layers 132m and the channel structure CH in the radial direction.

The second layer 156 may be located apart from the first layer 154. The second layer 156 may be located radially apart from the first layer 154 of the channel structure CH. A charge storage layer 155a, which will be described later, may be located between the second layer 156 and the first layer 154. The second layer 156 may be located between the charge storage layer 155a and the gate electrode 130. The second layer 156 may be on the outer surface of the charge storage layer 155a. The second layer 156 may have one side surface in contact with the outer surface of the charge storage layer 155a.

The second layer 156 may be extended in the third direction Z. In the embodiment, a portion of the second layer 156 may overlap the gate electrode 130 in a radial direction of the channel structure CH, and a remaining portion of the second layer 156 may overlap the plurality of interlayer insulation layers 132m in a radial direction of the channel structure CH.

In a semiconductor device according to the embodiment, the first layer 154 and the second layer 156 may include a ferroelectric material. For example, the first layer 154 and the second layer 156 may include a hafnium (Hf) compound having ferroelectric properties. For example, the first layer 154 and the second layer 156 may include HfO₂ doped with at least one of Si, Al, and Z. For example, the first layer 154 and the second layer 156 may include HfO₂, HfZnO, HfSiO, HfSiON, HfTaO, HfTiO, HfZrO or combinations thereof. In addition, the first layer 154 and the second layer 156 may include a ferroelectric material having a perovskite structure, such as PZT (PbZrₓTi₁₋ₓO₃), BaTiO₃, or PbTiO₃, for example. The first layer 154 and the second layer 156 may include at least one dopant selected from carbon (C), silicon (Si), magnesium (Mg), aluminum (Al), yttrium Y, nitrogen (N), germanium (Ge), tin (Sn), strontium (Sr), lead (Pb), calcium (Ca), barium (Ba), titanium (Ti), zirconium (Zr), gadolinium (Gd), and lanthanum (La). The first layer 154 and the second layer 156 may be formed of a crystalline material. For example, the first layer 154 and the second layer 156 may have a crystal structure of an orthorhombic system.

In embodiments, when the first layer 154 and the second layer 156 include ferroelectricity, the first layer 154 and the second layer 156 may be configured to have various polarization states depending on the voltage applied between the plurality of gate electrodes 130 and the channel layer 140. Specifically, remanent polarization may be generated in the first layer 154 and the second layer 156 by a voltage applied between the plurality of gate electrodes 130 and the channel structure CH.

The remanent polarization may be polarization remaining in the first layer 154 and the second layer 156 even after an electric field caused by a voltage applied between the gate electrode 130 and the channel layer 140 disappears, during an operation (e.g., program or erase operation) of the semiconductor device according to embodiments. The magnitude of the remanent polarization generated in the first layer 154 and the second layer 156 may be determined not only by the magnitude of the voltage applied between the plurality of gate electrodes 130 and the channel layer 140, but also by PV (polarization-voltage) hysteresis characteristic, which takes into account the history of the remanent polarization generated in the first layer 154 and the second layer 156. The generated remanent polarization may be stored in the first layer 154 and the second layer 156, and signal information may be non-volatilely stored by the stored remanent polarization. The first layer 154 and the second layer 156 may function as non-volatile memory layers.

The charge storage layer 155a may surround the inner surface of the first layer 154. The charge storage layer 155a may have an annulus shape on a plane. The charge storage layer 155a may be located between the first layer 154 and the second layer 156. The charge storage layer 155a may have one side surface in contact with the first layer 154. The other side surface of the charge storage layer 155a may be in contact with the second layer 156. The charge storage layer 155a may be a layer in which charges are trapped during a program operation of a semiconductor device according to the embodiment. For example, the charge storage layer 155a may include a plurality of charges that pass through the second layer 156 and flow into the interior of the charge storage layer 155a during a program or erase operation of the semiconductor device according to the embodiment. The charge storage layer 155a may function as a data storage area.

The charge storage layer 155a may include an insulating material. For example, the charge storage layer 155a may include an insulating material other than a ferroelectric material and an antiferroelectric material. For example, the charge storage layer 155a may include a paraelectric material. The charge storage layer 155a may include an insulating material capable of trapping charges. In embodiments, the charge storage layer 155a may include an oxide. For example, the charge storage layer 155a may include at least one of Al₂O₃, SiO₂, and AlSiO. However, it is not limited thereto, and the charge storage layer 155a may include various insulating materials capable of trapping charges. For example, the charge storage layer 155a may include polysilicon or SiNₓ. In embodiments, the dielectric constant of the insulating material included in the charge storage layer 155a may be smaller than or equal to the dielectric constant of the ferroelectric material (or antiferroelectric material) included in the first layer 154 or the second layer 156.

In the same or similar semiconductor device as illustrated in FIG. 1 to FIG. 5, the memory window may be determined by remanent polarization in the first layer 154 and the second layer 156, and charges trapped in the charge storage layer 155a. For example, in the semiconductor device according to embodiments, the memory window may have a larger value as the magnitude of the maximum remanent polarization that can be formed in the first layer 154 and the second layer 156 increases. For example, in a semiconductor device according to the embodiment, the memory window may have a higher value as the amount of charge that can be trapped in the charge storage layer 155a increases. The semiconductor device according to the embodiment may store information not only in the first layer 154 and the second layer 156, but also in the charge storage layer 155a, and thus may have a larger memory window compared to a case that does not include the charge storage layer 155a.

In the embodiment, the charge storage layer 155a may be located between the first layer 154 and the second layer 156. During a program or erase operation of the semiconductor device, electrons or holes may flow from the gate electrode 130 through the second layer 156 into the charge storage layer 155a, and may be trapped inside the charge storage layer 155a. After the electric field for the program or erase operation is removed, the first layer 154 and the second layer 156 may function as barriers that prevent electrons or holes trapped in the charge storage layer 155a from escaping back to the gate electrode 130. In the embodiment, the first layer 154 or the second layer 156 may prevent charges trapped in the charge storage layer 155a from escaping back to the gate electrode 130, thereby improving the retention characteristics of the semiconductor device according to the embodiment.

In another embodiment, the first layer 154 and the second layer 156 may include an anti-ferroelectric material. For example, the first layer 154 and the second layer 156 may include an antiferroelectric material such as ZrO₂ or [HfO₂]ₓ[ZrO₂]₍₁₋ₓ₎(0.5≤x≤1). For example, [HfO₂]ₓ[ZrO₂]₍₁₋ₓ₎ may be a mixture (or solid solution) of HfO₂ and ZrO₂. For example, the first layer 154 and the second layer 156 may include a two-dimensional antiferroelectric material. For example, the first layer 154 and the second layer 156 may include at least one of AgBiP₂Se₆, CuInP₂S₆, CuBiP₂Se₆, In₂Se₃, SnS, BN, and graphene (or twisted graphene). For example, the first layer 154 and the second layer 156 may include a perovskite material. For example, the first layer 154 and the second layer 156 may include at least one of PbZrO₃, PbHfO₃, (Na_{0.5}Bi_{0.5})TiO₃, Pb(Yb_{0.5}Nb_{0.5})O₃, Pb(Lu_{0.5}Nb_{0.5})O₃, Pb(Co_{0.5}W_{0.5})O₃, Pb(Mg_{0.5}W_{0.5})O₃, and Pb(In_{0.5}Nb_{0.5})O₃. For example, the first layer 154 and the second layer 156 may include BiFeO₃. In this case, at least a portion of Bi may be replaced by a substance such as Sm or Dy. For example, the first layer 154 and the second layer 156 may include AgNbO₃, NaNbO₃, [PbTiO₃]x[PbZrO₃]₍₁₋ₓ₎. [PbTiO₃]ₓ[PbZrO₃]₍₁₋ₓ₎may be, for example, a mixture (or solid solution) of PbTiO₃ and PbZrO₃. For example, the first layer 154 and the second layer 156 may include (NH4)H₂PO₄. For example, the first layer 154 and the second layer 156 may include at least one of BaFe₁₂O₁₉, SrFe₁₂O₁₉, and PbFe₁₂O_{19.}

Some of the charges trapped in the charge storage layer 155a may be combined with polarization charges having an opposite polarity at the interface between the charge storage layer 155a and the first layer 154, or between the charge storage layer 155a and the second layer 156, thereby compensating the polarization charges. When charges that have compensated polarization charges at the interfaces between the charge storage layer 155a and the first layer 154 and the second layer 156 are detrapped, remanent polarization formed in the first layer 154 and the second layer 156 may be depolarized, and in this case, the memory window of the semiconductor device according to the embodiment may decrease.

In general, the smaller the remanent polarization formed in layers including a ferroelectric or antiferroelectric material, the fewer the charges that may be combined with the polarization charges at the interfaces. In the embodiment, the first layer 154 and the second layer 156 may include an antiferroelectric material. Antiferroelectric materials may have less remanent polarization than ferroelectric materials. According to embodiments, charges combined with polarization charges at the interface between the charge storage layer 155a and the first layer 154, or at the interface between the charge storage layer 155a and the second layer 156, may be reduced. As a result, depolarization of the remanent polarization formed in the first layer 154 and the second layer 156 may be reduced, thereby improving the retention characteristics of the semiconductor device according to the embodiment.

In another embodiment, one of the first layer 154 and the second layer 156 may include a ferroelectric material and the other may include an antiferroelectric material. Since the effects of the case where the first layer 154 and the second layer 156 include a ferroelectric material or an antiferroelectric material are the same as or similar to those described in the foregoing embodiments, detailed descriptions thereof will be omitted.

The semiconductor device 10 according to the embodiment may further include a first horizontal conductive layer 112 and a second horizontal conductive layer 114 positioned between the second substrate 110 and the gate stack structure 120 or between the second substrate 110 and the channel structure CH. In the cell array region 102, the first horizontal conductive layer 112 may be on the second substrate 110. The first horizontal conductive layer 112 may electrically connect the channel structure CH and the second substrate 110. The first horizontal conductive layer 112 may function as a part of a common source line (for example, see CSL of FIG. 25) of the semiconductor device 10. For example, the first horizontal conductive layer 112 may function as a common source line together with the second substrate 110.

The first horizontal conductive layer 112 may be penetrated by a channel structure CH. In a region where the first horizontal conductive layer 112 is located, the multi-layered structure 150 and the channel insulation layer 143 of the channel structure CH may be removed, so that the first horizontal conductive layer 112 may be connected to the channel layer 140. That is, the first horizontal conductive layer 112 may be in direct contact with the channel layer 140. Accordingly, the first horizontal conductive layer 112 may electrically connect the second substrate 110 and the channel layer 140.

Meanwhile, in some regions of a contact region 104 to be described later, the first horizontal conductive layer 112 may not be provided between the second substrate 110 and the gate stack structure 120. In this case, a horizontal insulation layer 116 may be provided between the second substrate 110 and the gate stack structure 120. The horizontal insulation layer 116 may include various insulating materials. For example, the horizontal insulation layer 116 may include silicon oxide (SiO₂) and/or silicon nitride (SiNₓ). The horizontal insulation layer 116 may be a remaining material in some regions of the contact region 104 during a replacement process for forming the first horizontal conductive layer 112. The horizontal insulation layer 116 may be formed of the plurality of layers, but is not limited thereto.

The second horizontal conductive layer 114 may be on the first horizontal conductive layer 112 and the horizontal insulation layer 116. The second horizontal conductive layer 114 may extend along the first direction X and the second direction Y in the cell array region 102 and the contact region 104. The second horizontal conductive layer 114 may electrically connect the channel structure CH and the second substrate 110 together with the first horizontal conductive layer 112. The second horizontal conductive layer 114 may function as part of a common source line of the semiconductor device 10. The second horizontal conductive layers 114 may be penetrated by a channel structure CH.

The second horizontal conductive layer 114 may be used as a support layer to prevent the mold stack from collapsing or falling during a replacement process for forming the first horizontal conductive layer 112.

The first and second horizontal conductive layers 112, 114 may include a semiconductor material (e.g., polysilicon). For example, the first horizontal conductive layer 112 may include doped polysilicon, and the second horizontal conductive layer 114 may include doped polysilicon or may be a layer including impurities diffused from the first horizontal conductive layer 112. However, the embodiment is not limited thereto, and the second horizontal conductive layer 114 may include an insulating material. Alternatively, the second horizontal conductive layer 114 may not be separately provided.

As described above, when the gate stack structure 120 includes a plurality of gate stack structures 120a, 120b that are stacked on each other, the channel structure CH may have a plurality of channel structures CH1, CH2 that penetrate the plurality of gate stack structures 120a, 120b, respectively. For example, when the plurality of gate stack structures 120 include a first gate stack structure 120a and a second gate stack structure 120b, the plurality of channel structures CH may include a first channel structure CH1 extending through the first gate stack structure 120a, and a second channel structure CH2 extending through the second gate stack structure 120b.

The first channel structure CH1 and the second channel structure CH2 may have a connected structure. The first channel structure CH1 and the second channel structure CH2 may each have inclined side surfaces such that, in a cross-sectional view, the width becomes narrower toward the second substrate 110 depending on the aspect ratio. As shown in FIG. 3, a bent portion may be provided at the connection region between the first channel structure CH1 and the second channel structure CH2 due to a difference in width. As another example, as shown in FIG. 4, the first channel structure CH1 and the second channel structure CH2 may have inclined side surfaces that are continuously connected without the bent portion. However, the shapes of the first channel structure CH1 and the second channel structure CH2 are not limited thereto and may be changed in various ways.

In FIG. 1 and FIG. 2, an example is illustrated in which the channel layer 140, the core insulation layers 142, and the multi-layered structure 150 of the first channel structure CH1 and the second channel structure CH2 are formed to extend continuously and have an integral structure. After forming a first through-hole for the first channel structure CH1 and a second through-hole for the second channel structure CH2, the multi-layered structure 150, the channel layer 140, and the core insulation layers 142 may be formed over the entire area of the first and second through-holes to form the above-described structure. However, the embodiment is not limited thereto. As another example, the channel layer 140, the core insulation layers 142, and the multi-layered structure 150 of the first channel structure CH1 and the second channel structure CH2 may be separately formed and electrically connected to each other. For example, after forming a first through-hole for the first channel structure CH1, the multi-layered structure 150, the channel layer 140, and the core insulation layers 142 may be formed in the first through-hole. Then, after forming a second through-hole for the second channel structure CH2, the multi-layered structure 150, the channel layer 140, and the core insulation layers 142 may be formed in the second through-hole. Many other changes are possible.

In an exemplary embodiment, the channel pad 144 may be provided on the channel structure CH (for example, a second channel structure CH2) provided on the gate stack structure 120 (for example, a second gate stack structure 120b) positioned at an upper position among a plurality of gate stack structures 120. Alternatively, channel pads 144 may be provided on each of the first channel structure CH1 and the second channel structure CH2. In this case, the channel pad 144 of the first channel structure CH1 may be connected to the channel layer 140 of the second channel structure CH2.

In the embodiment, the gate stack structure 120 may extend in a direction crossing the second substrate 110 (e.g., a third direction Z) and may be partitioned into a plurality of sections in a plan view by the separation structure 146 penetrating the gate stack structure 120.

For example, the separation structure 146 may extend through the plurality of gate electrodes 130 and the cell insulation layer 132 to the upper surface of the second substrate 110. In a plan view, the separation structures 146 may extend in the first direction X and may be provided as a plurality of structures spaced apart from each other at predetermined intervals in the second direction Y that intersects the first direction X. Accordingly, in the plan view, the plurality of gate stack structures 120 may each extend in the first direction X and may be spaced apart from each other at predetermined intervals in the second direction Y. The gate stack structure 120 partitioned by the separation structure 146 may constitute a memory cell block. However, the embodiment is not limited thereto and the scope of the memory cell block is not limited thereto.

For example, the separation structure 146 may have a sloped side surface whose width decreases toward the second substrate 110 when viewed in cross section due to its high aspect ratio. However, the embodiment is not limited thereto, and the side surface of the separation structure 146 may be perpendicular to the second substrate 110. In FIG. 2, it is illustrated that, in a cross-sectional view, the separation structure 146 has continuous inclined side surfaces between the first gate stack structure 120a and the second gate stack structure 120b without a bent portion. However, the embodiment is not limited thereto, and the separation structure 146 may include a bent portion at a boundary between the first gate stack structure 120a and the second gate stack structure 120b.

The separation structure 146 may be filled with various insulating materials. For example, the separation structure 146 may include an insulating material such as silicon oxide, silicon nitride, or silicon oxynitride. However, the embodiment is not limited thereto, and the structure, shape, material of the separation structure 146 may be variously modified.

The semiconductor device according to the embodiment may further include an upper separation pattern 148.

The upper separation pattern 148 may be located on an upper portion of the gate stack structure 120. In a plan view, the upper separation patterns 148 may extend in the first direction X and may be provided as a plurality of patterns spaced apart from each other at predetermined intervals in the second direction Y.

The upper separation pattern 148 may be formed by penetrating one or more gate electrodes 130 including an upper gate electrode 130U positioned between the separation structures 146. The upper separation pattern 148 may, for example, separate two gate electrodes 130 from each other in a second direction Y. However, the number of the plurality of gate electrodes 130 separated by the upper separation pattern 148 is not limited thereto and may be variously modified.

The upper separation pattern 148 may have a form filled with an insulating material. For example, the upper isolation pattern may include an insulating material such as silicon oxide (SiO₂), silicon nitride (SiNₓ), or silicon oxynitride (SiON). However, the embodiment is not limited thereto, and the structure, shape, material of the upper separation pattern 148 may be variously changed.

The circuit region 200 may include a first substrate 210, a circuit element 220 on the first substrate 210, and a first wiring portion 230.

The first substrate 210 may be a semiconductor substrate including a semiconductor material. For example, the first substrate 210 may be a semiconductor substrate made of a semiconductor material, or may be a semiconductor substrate in which a semiconductor layer is formed on a base substrate. For example, the first substrate 210 may be composed of silicon, epitaxial silicon, germanium, silicon-germanium, silicon-on-insulator (SOI), or germanium-on-insulator (GOI).

The circuit element 220 formed on the first substrate 210 may include various circuit elements for controlling the operation of the memory cell structure provided in the cell region 100. For example, the circuit element 220 may constitute peripheral circuit structures such as a decoder circuit (reference numeral 1110 in FIG. 25), a page buffer (see 1120 in FIG. 25), and a logic circuit (see 1130 in FIG. 25).

The circuit elements 220 may include transistors for example, but are not limited thereto,. For example, the peripheral circuit elements 220 may include not only active elements such as transistors, but also passive elements such as capacitors, resistors, and inductors.

A first wiring portion 230 on a first substrate 210 may be electrically connected to a circuit element 220. In an exemplary embodiment, a first wiring portion 230 may include a plurality of wiring layers 236 that are spaced apart with a first insulation layer 232 interposed therebetween and are connected by contact vias 234 to form a desired path. The wiring layer 236 or contact via 234 may include various conductive materials, and the first insulation layer 232 may include various insulating materials.

In order to connect the gate stack structure 120 and channel structure CH provided in the cell array region 102 to the circuit region 200 or an external circuit, a contact region 104 and a second wiring portion 180 may be provided.

Here, the second wiring portion 180 may include all elements that electrically connect the plurality of gate electrodes 130, the channel structure CH, and/or the second substrate 110 to the circuit region 200 or an external circuit. For example, the second wiring portion 180 may include a bit line 182, a gate contact portion 184, a source contact portion 186, an input/output connection wiring 188, and a contact via 180a connected to each of these, and a connection wiring 180b connecting these.

The bit line 182 may be on the cell insulation layer 132 of the gate stack structure 120 formed in the cell array region 102. The bit line 182 may extend in the second direction Y. The bit line 182 may be electrically connected to the channel structure CH, for example, thee channel pad 144, through the contact via 180a, for example, the bitline contact via.

The contact region 104 may be placed around the cell array region 102. A part of the second wiring portion 180 may be located in the contact region 104. The contact region 104 may include a gate stack structure 120 on a second substrate 110, and a gate contact portion 184 for connecting a plurality of gate electrodes 130 of the cell array region 102 to a the circuit region 200 or an external circuit.

More specifically, in the contact region 104, a plurality of gate electrodes 130 may be positioned to extend in a third direction Z along a first direction X, and the extension lengths of the plurality of gate electrodes 130 in the contact region 104 may gradually decrease as they become farther from the second substrate 110. For example, the plurality of gate electrodes 130 may be positioned in a stepped shape in the contact region 104. In this case, the plurality of gate electrodes 130 may have a stepped shape in one direction or in the plurality of directions. In the contact region 104, a plurality of gate contact portions 184 may be electrically connected to a plurality of gate electrodes 130 extending through the cell insulation layer 132 to the contact region 104.

And in the contact region 104, the source contact portion 186 may penetrate the cell insulation layer 132 and be electrically connected to the second substrate 110. For example, the source contact portion 186 may be electrically connected to the second substrate 110 by penetrating the second horizontal conductive layer 114 and the horizontal insulation layer 116.

The input/output connection wiring 188 may penetrate the gate stack structure 120 or be arranged on the outside of the gate stack structure 120 to be electrically connected to the first wiring portion 230 of the circuit region 200. However, it is not limited thereto, and the input/output connection wiring 188 may be electrically connected to the first wiring portion 230 of the circuit region 200 by penetrating the gate stack structure 120.

A connection wiring 180b may be located in the cell array region 102 and/or the contact region 104. A bit line 182, a gate contact portion 184, a source contact portion 186, and/or an input/output connection wiring 188 may be electrically connected to the connection wiring 180b. For example, the gate contact portion 184, the source contact portion 186, and/or the input/output connection wiring 188 may be connected to the connection wiring 180b through the contact via 180a.

In FIG. 1, the connection wiring 180b is provided as a single layer located on the same plane as the bit line 182, and the second insulation layer 134 is located in a part other than the second wiring portion 180. However, this is only a simplified illustration for convenience. Accordingly, the connection wiring 180b may include the plurality of wiring layers and further include contact vias for electrical connection with the bit line 182, the gate contact portion 184, the source contact portion 186, and/or the input/output connection wiring 188.

In this way, the bit line 182, the plurality of gate electrodes 130, and/or the second substrate 110 connected to the channel structure CH may be electrically connected to the circuit element 220 of the circuit region 200 by the second wiring portion 180 and the first wiring portion 230.

In FIG. 1, it is illustrated that a gate contact portion 184, a source contact portion 186, and/or an input/output connection wiring 188 have inclined side surfaces such that, in a cross-sectional view, the width becomes narrower toward the second substrate 110 depending on the aspect ratio, and a bent portion is provided at a boundary between the first gate stack structure 120a and the second gate stack structure 120b. However, the examples are not limited to this. For example, the gate contact portion 184, the source contact portion 186, and/or the input/output connection wiring 188 may also be formed without a bent portion at the boundary between the first gate stack structure 120a and the second gate stack structure 120b. Many other changes are possible.

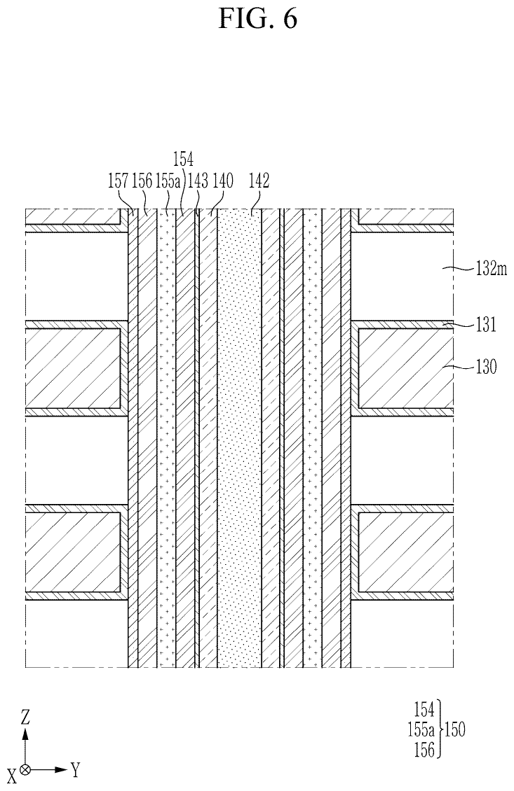

FIG. 6 is a drawing for explaining a semiconductor device according to embodiments. Specifically, FIG. 6 is an enlarged cross-sectional view of area A of FIG. 2. The semiconductor device illustrated in FIG. 6 has many similarities to the previous embodiments, so the following description focuses mainly on the differences from the previous embodiments.

The semiconductor device according to the embodiment may further include a gate insulation layer 157 positioned between the second layer 156 and the gate electrode 130. During a program or erase operation of a semiconductor device according to embodiments, charges may flow into the gate insulation layer 157. Charges flowing into the gate insulation layer 157 may compensate for polarization charges at the interface between the gate insulation layer 157 and the second layer 156. The gate insulation layer 157 may also be located between the interlayer insulation layer 132m and the second layer 156.

Referring to FIG. 6, the gate insulation layer 157 may surround at least a portion of the outer surface of the second layer 156. One side surface of the gate insulation layer 157 may be in contact with the outer surface of the second layer 156. The opposite side surface of the gate insulation layer 157 may be in contact with the barrier layer 131 and the interlayer insulation layer 132m. When the semiconductor device according to the embodiment does not include a barrier layer 131, the opposite side surface of the gate insulation layer 157 may be in contact with the gate electrode 130 and the interlayer insulation layer 132m.

The gate insulation layer 157 may include an insulating material. For example, the gate insulation layer 157 may include SiO₂, SiNₓ, SiON, and combinations thereof, but is not limited thereto ..

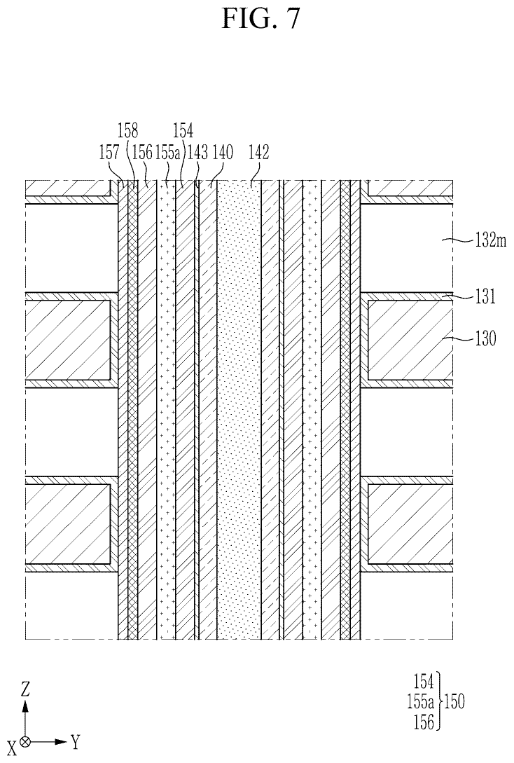

FIG. 7 is a drawing for explaining a semiconductor device according to embodiments. Specifically, FIG. 7 is an enlarged cross-sectional view of area A of FIG. 2. The semiconductor device illustrated in FIG. 7 has many similarities to the previous embodiments, so the following description focuses mainly on the differences from the previous embodiments.

A semiconductor device according to embodiments may include a gate insulation layer 157 and an additional charge storage layer 158 positioned between a second layer 156 and a gate electrode 130. In embodiments, an additional charge storage layer 158 and a gate insulation layer 157 may be sequentially stacked on the outer surface of the second layer 156. Referring to FIG. 7, the additional charge storage layer 158 may surround the outer surface of the second layer 156. One side surface of the additional charge storage layer 158 may be in contact with the outer surface of the second layer 156. The opposite side surface of the additional charge storage layer 158 may be in contact with the gate insulation layer 157.

The gate insulation layer 157 may surround the outer surface of the additional charge storage layer 158. One side surface of the gate insulation layer 157 may be in contact with the outer surface of the additional charge storage layer 158. The opposite side surface of the gate insulation layer 157 may be in contact with the barrier layer 131 and the interlayer insulation layer 132m. When the semiconductor device according to the embodiment does not include a barrier layer 131, the opposite side surface of the gate insulation layer 157 may be in contact with the gate electrode 130 and the interlayer insulation layer 132m. The gate insulation layer 157 and the additional charge storage layer 158 may be extended in the third direction Z.

The additional charge storage layer 158 may include an insulating material. The additional charge storage layer 158 may include an insulating material capable of trapping charges. In embodiments, the additional charge storage layer 158 may include an insulating material different from the insulating material included in the charge storage layer 155a. In embodiments, the additional charge storage layer 158 may comprise a nitride. For example, the additional charge storage layer 158 may include SiNₓ, but is not limited thereto, and may include various insulating materials capable of trapping charges.

During a program or erase operation of the semiconductor device according to the embodiment, charges may be trapped in the additional charge storage layer 158, and thus, a memory window of the semiconductor device according to the embodiment may increase. In the embodiment, the gate insulation layer 157 may prevent charges trapped in the additional charge storage layer 158 from escaping back to the gate electrode 130.

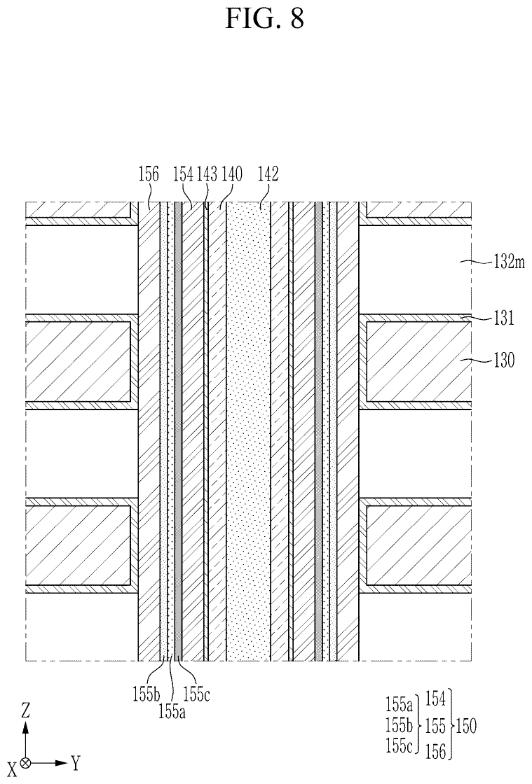

FIG. 8 is a drawing for explaining a semiconductor device according to embodiments. Specifically, FIG. 8 is an enlarged cross-sectional view of area A of FIG. 2. The semiconductor device illustrated in FIG. 8 has many similarities to the previous embodiments, so the following description focuses mainly on the differences from the previous embodiments.

Referring to FIG. 8, in the semiconductor device according to embodiments, a third layer 155 including at least one insulation layer may be positioned between the first layer 154 and the second layer 156. Specifically, in the semiconductor device according to the embodiment, a charge storage layer 155a and a first passivation layer 155b and a second passivation layer 155c positioned on both side surfaces of the charge storage layer 155a may be included between the first layer 154 and the second layer 156. In embodiments, the second passivation layer 155c, the charge storage layer 155a, and the first passivation layer 155b may be sequentially stacked on the outer surface of the first layer 154. In embodiments, the thickness of each of the first passivation layer 155b and the second passivation layer 155c along the radial direction of the channel structure CH (for example, along the second direction Y in FIG. 8) may be less than or equal to the thickness of the charge storage layer 155a, but is not limited thereto.

In the embodiment, the passivation layers 155b, 155c may reduce vacancy defects that may be present on the surface of the first layer 154 or the second layer 156 at the interface with the first layer 154 or the second layer 156. For example, when the first layer 154 or the second layer 156 includes a ferroelectric or antiferroelectric material, and the ferroelectric or antiferroelectric material includes an oxide (e.g., HfO₂), the material (e.g., nitrogen (N) atoms) included in the passivation layers 155b, 155c may combine with oxygen vacancy defects located on the surface of the first layer 154 or the second layer 156, and thus the number of vacancy defects on the surface of the first layer 154 or the second layer 156 may be reduced. For example, as the program/erase cycle of a semiconductor device increases, oxygen atoms included in an oxide (e.g., HfO₂) in the first layer 154 or the second layer 156 may migrate to the surface of the first layer 154 or the second layer 156 and combine with oxygen vacancy defects. In this case, as the program/erase cycle increases, the memory window of the semiconductor device may gradually decrease, and thus the reliability of the semiconductor device may deteriorate. In the case of the semiconductor device according to embodiments, vacancy defects on the surface of the first layer 154 or the second layer 156 may be reduced, and thus the endurance of the semiconductor device may be improved.

In embodiments, the first passivation layer 155b and the second passivation layer 155c may include nitride. For example, the first passivation layer 155b and the second passivation layer 155c may include at least one of AlN and AlSiON, but are not limited thereto.

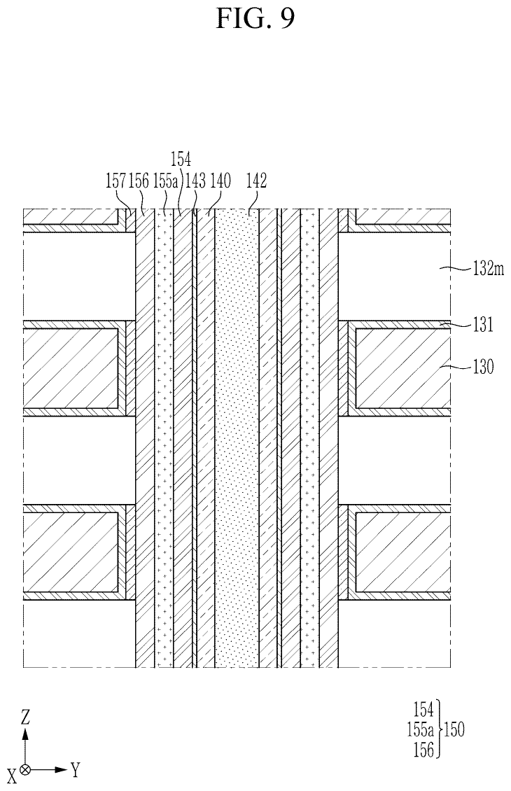

FIG. 9 is a drawing for explaining a semiconductor device according to embodiments. Specifically, FIG. 9 is an enlarged cross-sectional view of area A of FIG. 2. The semiconductor device illustrated in FIG. 9 has many similarities to the previous embodiments, so the following description focuses mainly on the differences from the previous embodiments.

Referring to FIG. 9, the semiconductor device according to the embodiment may further include a gate insulation layer 157 positioned between the second layer 156 and the gate electrode 130. In embodiments, the gate insulation layer 157 may overlap the gate electrode 130 in the second direction Y. In embodiments, the gate insulation layer 157 may not overlap with the interlayer insulation layer 132m in the second direction Y. Unlike the semiconductor device described with reference to FIG. 6, in the embodiment, the gate insulation layer 157 may be located only on a portion of the entire outer surface area of the second layer 156.

Referring to FIG. 9, one side surface of the gate insulation layer 157 may be in contact with the outer surface of the second layer 156. The opposite side surface of the gate insulation layer 157 may be in contact with the barrier layer 131. When the semiconductor device according to the embodiment does not include the barrier layer 131, the opposite side surface of the gate insulation layer 157 may be in contact with the gate electrode 130. In the embodiment, at least a portion of the area of the outer surface of the second layer 156 that is not in contact with the gate insulation layer 157 may be in contact with the interlayer insulation layer 132m. In the embodiment, the gate insulation layer 157 may include a region overlapping the interlayer insulation layer 132m in the third direction Z.

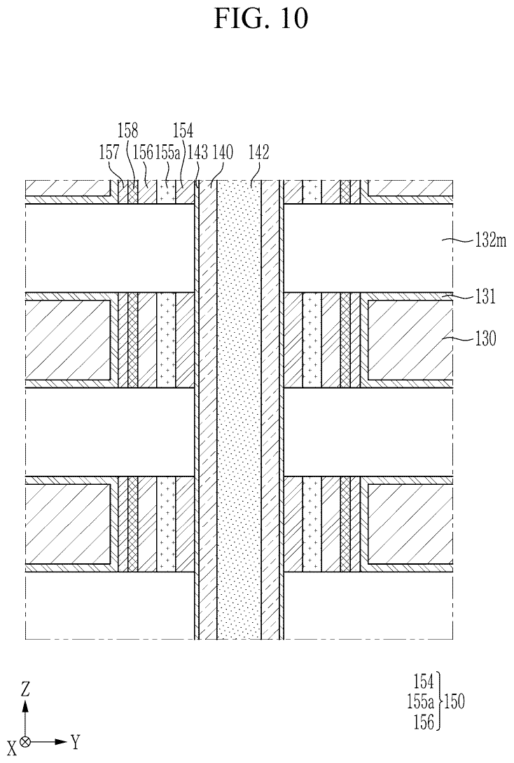

FIG. 10 is a drawing for explaining a semiconductor device according to embodiments. Specifically, FIG. 10 is an enlarged cross-sectional view of area A of FIG. 2. The semiconductor device illustrated in FIG. 10 has many similarities to the previous embodiments, so the following description focuses mainly on the differences from the previous embodiments.

Referring to FIG. 10, the semiconductor device according to the embodiment may further include a gate insulation layer 157 and an additional charge storage layer 158 positioned between the second layer 156 and the gate electrode 130. In embodiments, the gate insulation layer 157, the additional charge storage layer 158, and the multi-layered structure 150 may overlap in the second direction Y. In embodiments, the gate insulation layer 157, the additional charge storage layer 158, and the multi-layered structure 150 may not overlap with the interlayer insulation layer 132m in the second direction Y.

Unlike the semiconductor device described with reference to FIG. 7, in the semiconductor device according to the embodiment, the gate insulation layer 157, the additional charge storage layer 158, and the multi-layered structure 150 may be located only on a part of the entire area of the outer surface of the channel structure CH. Referring to FIG. 10, the gate insulation layer 157, the additional charge storage layer 158, and the multi-layered structure 150 may be only on a portion of the entire outer surface area of the channel structure CH that overlaps the gate electrode 130 and/or the barrier layer 131 in the second direction Y. The gate insulation layer 157, the additional charge storage layer 158, and the multi-layered structure 150 may not be on a portion of the entire outer surface area of the channel structure CH that overlaps the interlayer insulation layer 132m in the second direction Y.

According to embodiments, charges trapped inside the additional charge storage layer 158 and the multi-layered structure 150 may be prevented from being detrapped and moving in the third direction Z, and thus, the retention characteristics of the semiconductor device according to the embodiment may be improved.

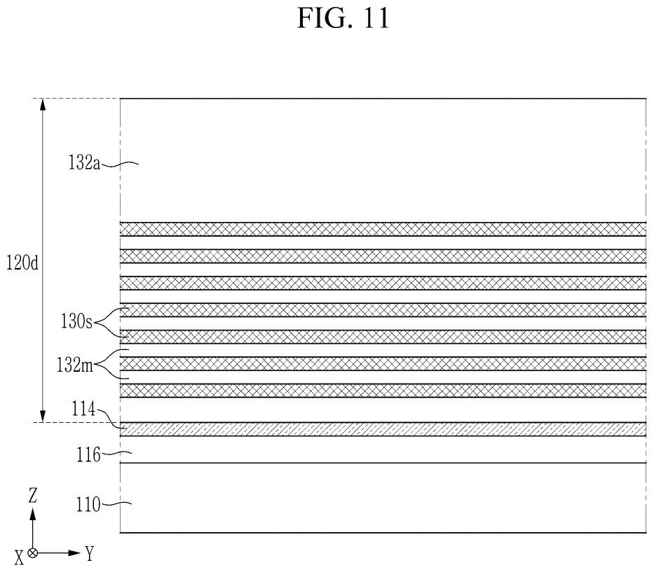

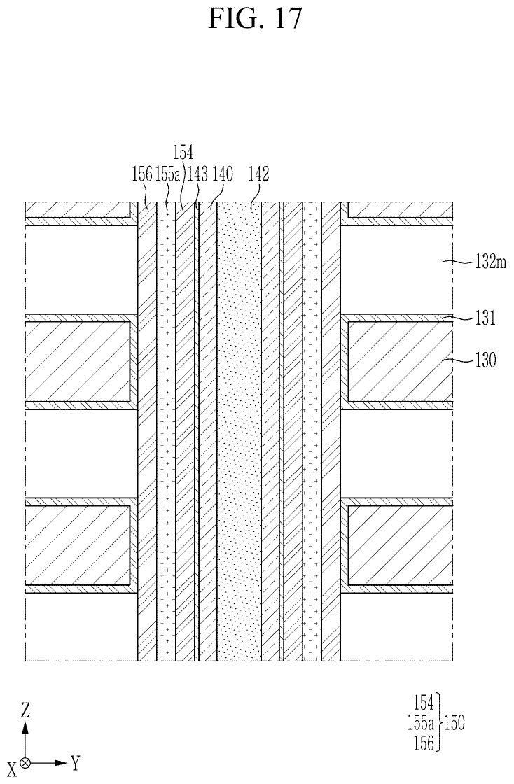

FIG. 11 to FIG. 17 are process cross-sectional views for explaining a method for manufacturing a semiconductor device according to embodiments. Specifically, FIG. 11 to FIG. 17 are process cross-sectional views for explaining the manufacturing method of the semiconductor device described with reference to FIG. 1 to FIG. 5.

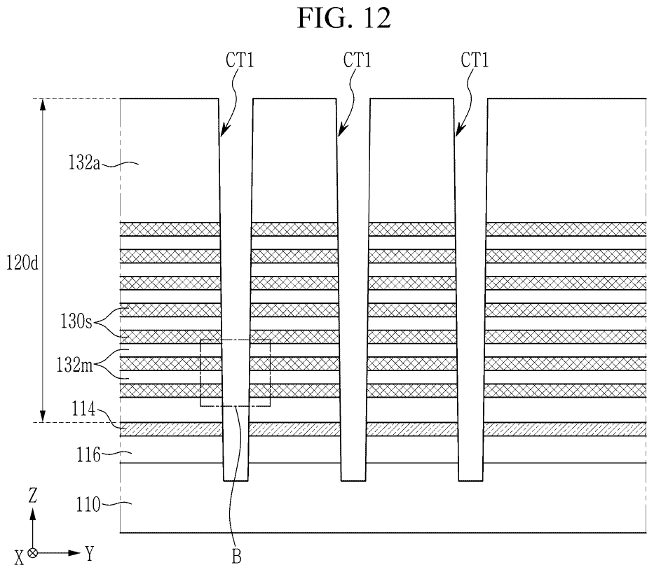

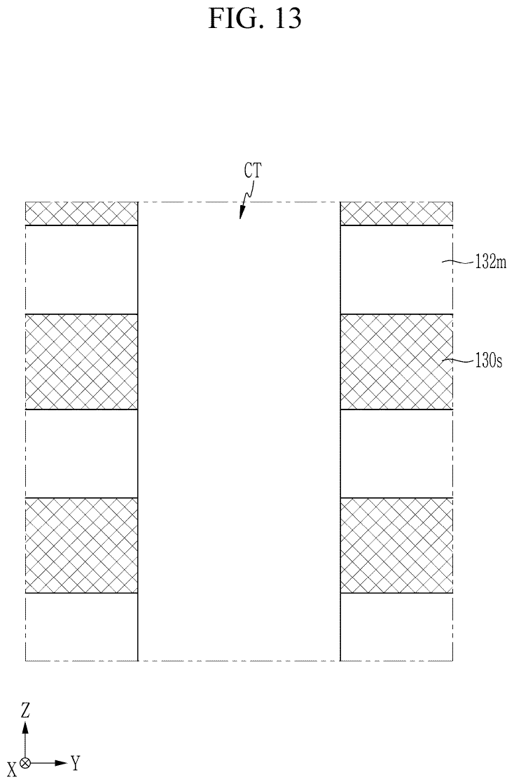

FIG. 11 and FIG. 12 are cross-sectional views of intermediate steps of a method for manufacturing a semiconductor device according to embodiments. FIG. 13 to FIG. 17 are cross-sectional views corresponding to area B of FIG. 12, showing intermediate steps of a method for manufacturing the semiconductor device according to embodiments.

In FIG. 11 and FIG. 12, only the cell structure is illustrated for convenience, and the illustration of the circuit area including the peripheral circuit area is omitted. In addition, although FIG. 11 and FIG. 12 illustrate that the stack structure 120d is formed as a single stacked structure, it is not limited thereto and may be formed as two or more stacked structures. Hereinafter, a method for manufacturing a channel structure CH and a multi-layered structure 150 of the semiconductor device according to embodiments will be mainly described.

As illustrated in FIG. 11, a horizontal insulation layer 116 and a second horizontal conductive layer 114 may be stacked on the second substrate 110, and the stack structure 120d may be formed on the second horizontal conductive layer 114. A circuit area may be formed below the second substrate 110, but illustration of the circuit area is omitted. For example, a circuit area may be formed first and then a second substrate 110 may be formed over the circuit area. However, it is not limited thereto, and the structure under the second substrate 110 and the method of forming the same may be variously modified

First, a horizontal insulation layer 116 may be formed by depositing an insulating material on a second substrate 110. The second substrate 110 may include a semiconductor material (e.g., polysilicon). For example, the second substrate 110 may include polysilicon doped with impurities. However, the material of the second substrate 110 is not limited thereto and may be variously modified. For example, the second substrate 110 may include a conductive material or a metal silicide.

The horizontal insulation layer 116 may be composed of a single layer or the plurality of layers. For example, a horizontal insulation layer 116 may be formed by sequentially stacking silicon oxide (SiO₂) and silicon nitride (SiNₓ). At least a portion of the horizontal insulation layer 116 may be a layer to be replaced with the first horizontal conductive layer 112 (see FIG. 1) in a subsequent process. That is, the horizontal insulation layer 116 may be formed to include a region where the first horizontal conductive layer 112 (see FIG. 1) is to be formed. The horizontal insulation layer 116 may include a plurality of layers sequentially stacked on the second substrate 110, but is not limited thereto.

Next, a second horizontal conductive layer 114 may be formed on the horizontal insulation layer 116. The second horizontal conductive layer 114 may be formed using a semiconductor material (e.g., polysilicon). For example, the second horizontal conductive layer 114 may include polysilicon doped with impurities.

Next, a stacked structure 120d may be formed by alternately stacking a plurality of interlayer insulating layers 132m and a plurality of sacrificial insulating layers 130s on the second horizontal conductive layer 114. The plurality of interlayer insulation layers 132m and the plurality of sacrificial insulation layers 130s may be alternately stacked, and the first upper insulation layer 132a may be formed on the topmost layer.

The plurality of sacrificial insulation layers 130s may include silicon oxide (SiO₂), silicon nitride (SiNₓ), silicon oxynitride (SiON), and low-k materials. The plurality of sacrificial insulation layers 130s may include a different material than the plurality of interlayer insulation layers 132m. The plurality of sacrificial insulation layers 130s may include a material having an etching selectivity with respect to the plurality of interlayer insulation layers 132m. For example, the plurality of sacrificial insulation layers 130s may include at least one of silicon (Si), silicon nitride (SiNₓ), silicon carbide (SiC), and silicon oxynitride (SiON), but may be made of a different material from the plurality of interlayer insulation layers 132m. For example, the plurality of interlayer insulation layers 132m may include silicon oxide (SiO₂), and the plurality of sacrificial insulation layers 130s may include silicon nitride (SiNₓ). The plurality of sacrificial insulation layers 130s may be layers to be replaced with gate electrodes 130 (see FIG. 1) in a subsequent process. That is, the plurality of sacrificial insulation layers 130s may be formed to correspond to the portion where the gate electrode 130 (see FIG. 1) is to be formed.

In the drawings, the stack structure 120d is illustrated as being formed as a single stack structure; however, the embodiment is not limited thereto, and the stack structure 120d may include two or more stack structures.

As shown in FIG. 12 and FIG. 13, a channel hole CT may be formed by patterning a stack structure 120d. A portion of the stack structure 120d may be penetrated by a channel hole CT. In the process of patterning the stack structure 120d, the horizontal insulation layer 116 and the second substrate 110 may be patterned together. The horizontal insulation layer 116 may be penetrated by the channel hole CT, and the second substrate 110 may not be penetrated. That is, the depth of the channel hole CT formed in the second substrate 110 may be smaller than the thickness of the second substrate 110. Accordingly, the side surfaces of the plurality of sacrificial insulation layers 130s and the plurality of interlayer insulation layers 132m may be exposed.

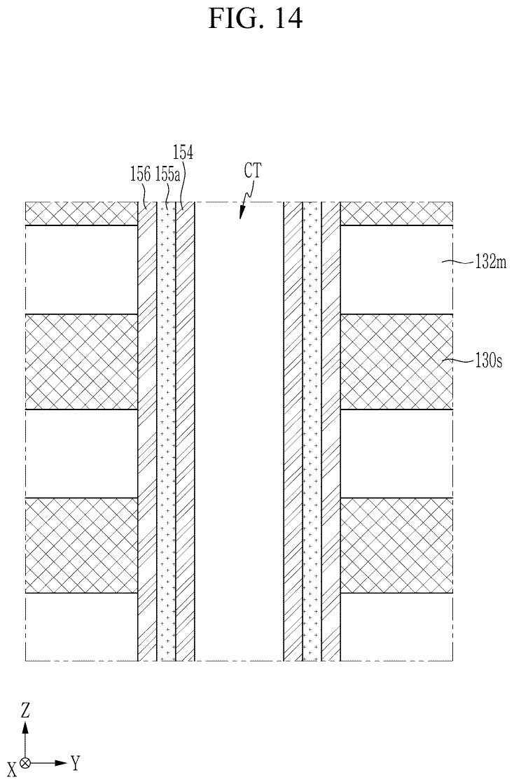

As illustrated in FIG. 14, a multi-layered structures 150 including a first layer 154, a second layer 156, and a charge storage layer 155a may be formed on the inner surface of a channel hole CT. In embodiments, a second layer 156, a charge storage layer 155a, and a first layer 154 may be sequentially formed on the inner surface of the channel hole CT.

The second layer 156 may be conformally formed on the inner surface of the channel hole CT. The second layer 156 may be formed to fill a portion of the channel hole CT. Next, a charge storage layer 155a may be formed on the inner surface of the second layer 156. The charge storage layer 155a may be conformally formed on the inner surface of the second layer 156. The charge storage layer 155a may fill a portion of the channel hole CT. Next, a first layer 154 may be formed on the inner surface of the charge storage layer 155a. The first layer 154 may be conformally formed on the inner surface of the charge storage layer 155a. The charge storage layer 155a may fill a portion of the channel hole CT. In embodiments, the first layer 154 may not completely fill the inside of the channel hole CT.

In embodiments, the first layer 154 and the second layer 156 may include a ferroelectric material. For example, the first layer 154 and the second layer 156 may include a hafnium (Hf) compound having ferroelectric properties. For example, the first layer 154 and the second layer 156 may include HfO₂ doped with at least one of Si, Al, and Zr, but are not limited thereto. In embodiments, the first layer 154 and the second layer 156 may include an antiferroelectric material.

In embodiments, the charge storage layer 155a may include an insulating material. For example, the charge storage layer 155a may include an insulating material other than a ferroelectric material and an antiferroelectric material. For example, the charge storage layer 155a may include a paraelectric material. For example, the charge storage layer 155a may include at least one of Al₂O₃, SiO₂, and AlSiO, but is not limited thereto. In embodiments, the dielectric constant of the insulating material included in the charge storage layer 155a may be smaller than or equal to the dielectric constant of the ferroelectric material or antiferroelectric material included in the first layer 154 or the second layer 156.

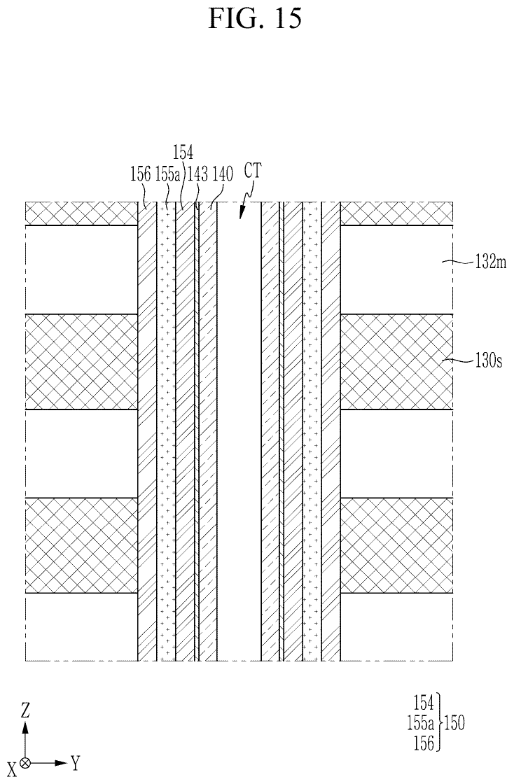

As illustrated in FIG. 15, a channel insulation layer 143 and a channel layer 140 may be formed on the inner surface of the first layer 154. The channel insulation layer 143 and the channel layer 140 may be sequentially stacked on the inner surface of the first layer 154. The channel insulation layer 143 may be, for example, a natural oxide film formed between the channel layer 140 and the first layer 154 when forming the channel layer 140 on the inner surface of the first layer 154, but is not limited thereto.

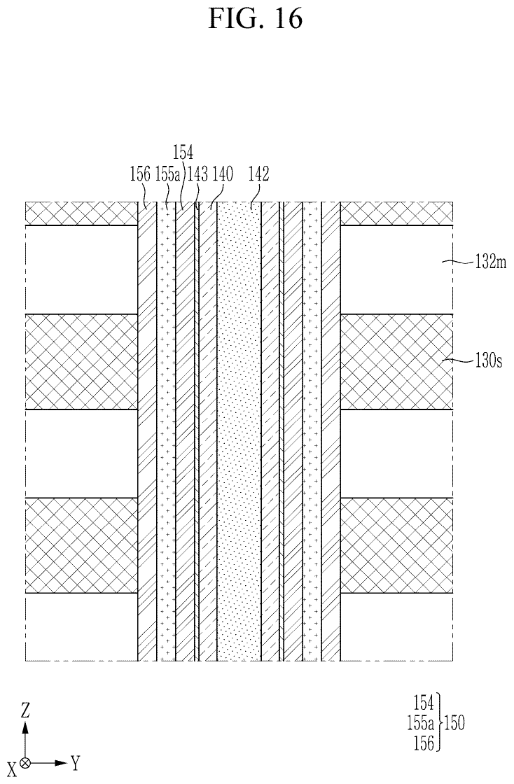

Next, as shown in FIG. 16, a core insulation layers 142 may be formed inside the channel hole CT, and a gate electrode 130 and a barrier layer 131 may be formed in regions where the sacrificial insulation layers 130s were located.

First, a core insulation layer 142 may be conformally formed on the inner surface of the channel layer 140. The core insulation layers 142 may be formed to completely fill the inside of the channel hole CT. Although not shown in the drawing, a channel pad may be further formed on the first layer 154, the charge storage layer 155a, the second layer 156, the channel insulation layer 143, the channel layer 140, and the core insulation layer 142.

Next, a plurality of sacrificial insulation layers 130s may be removed, and a barrier layer 131 and a plurality of gate electrodes 130 may be formed within the space from which the plurality of sacrificial insulation layers 130s have been removed. For example, after removing a plurality of sacrificial insulation layers 130s using an etching process, a barrier layer 131 may be conformally formed in the portion where the sacrificial insulation layers 130s were removed. In embodiments, the barrier layer 131 may be formed by atomic layer deposition (ALD), but is not limited thereto. Next, a metal material such as tungsten (W), copper (Cu), aluminum (Al), etc. may be deposited on the inner surface of the barrier layer 131 to form a gate electrode 130.

The plurality of gate electrodes 130 may include a lower gate electrode 130L, a memory cell gate electrode 130M, and an upper gate electrode 130U sequentially positioned from the second substrate 110. The lower gate electrode 130L may be used as a gate electrode of a ground selection transistor, the memory cell gate electrode 130M may form a memory cell, and the upper gate electrode 130U may be used as a gate electrode of a string selection transistor. Accordingly, a semiconductor device described with reference to FIG. 1 to FIG. 5 may be formed.

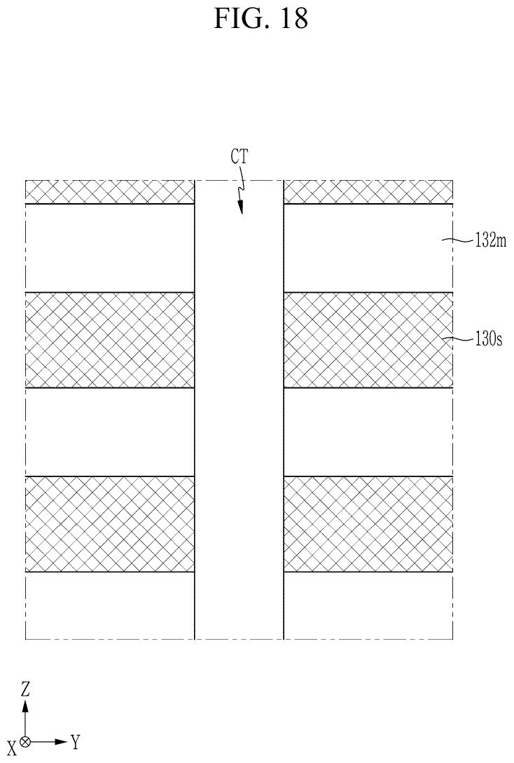

FIG. 18 to FIG. 23 are process cross-sectional views for explaining a method for manufacturing a semiconductor device according to embodiments. Specifically, FIG. 18 to FIG. 23 are process cross-sectional views for explaining a method for manufacturing a semiconductor device described with reference to FIG. 10. Hereinafter, differences will mainly be described in comparison with the process described with reference to FIG. 11 to FIG. 17.

First, as illustrated in FIG. 18, a horizontal insulation layer 116 and a second horizontal conductive layer 114 are stacked on a second substrate 110, and a plurality of interlayer insulation layers 132m and a plurality of sacrificial insulation layers 130s are alternately stacked on the second horizontal conductive layer 114 to form a stack structure 120d, and a channel hole CT penetrating a portion of the stack structure 120d in the third direction Z may be formed.

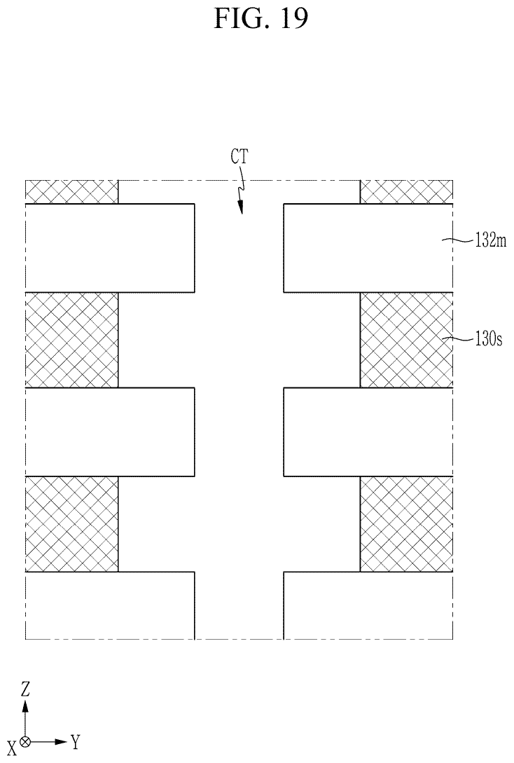

Next, as illustrated in FIG. 19, a recess RC may be formed by etching a portion of the plurality of sacrificial insulation layers 130s exposed through the channel hole CT.

In the embodiment, the process of etching the portion of the plurality of sacrificial insulation layers 130s may be performed using a wet etching process, but is not limited thereto. The plurality of sacrificial insulation layers 130s may include a material having an etching selectivity with respect to the plurality of interlayer insulation layers 132m, and thus, the interlayer insulation layers 132m may not be etched in the process of etching the plurality of sacrificial insulation layers 130s. The width of the recess RC in the third direction Z may be substantially the same as the width of each of the plurality of sacrificial insulation layers 130s in the third direction Z. The recess RC may extend radially from the inner wall of the channel hole CT along the radial direction of the channel hole CT. For example, the recess RC may extend along the second direction Y from the inner wall of the channel hole CT. As the recess RC is formed, a portion of the upper surface and a portion of the lower surface of the plurality of interlayer insulation layers 132m may be exposed.

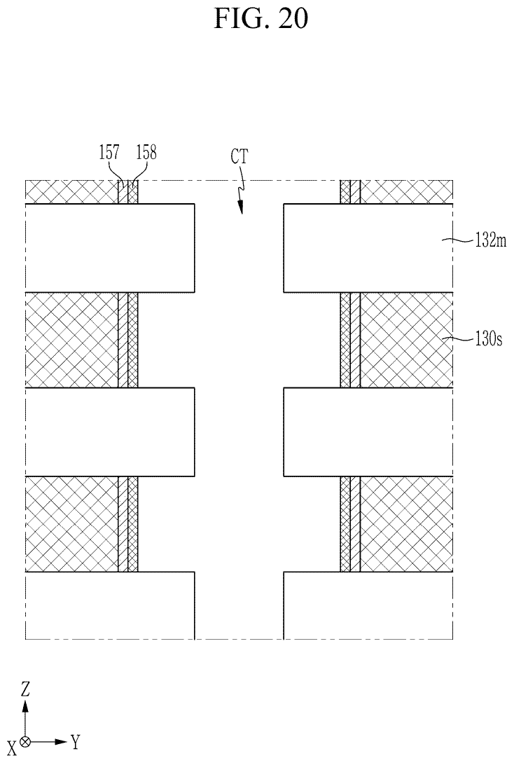

As illustrated in FIG. 20, a gate insulation layer 157 and an additional charge storage layer 158 may be sequentially formed on the sacrificial insulation layer 130s located on the bottom surface of the recess RC.

First, the additional charge storage layer 158 may be conformally formed on the side surface of the sacrificial insulation layer 130s exposed through the channel hole CT and the recess RC and on the portion of the upper surface and the portion of the lower surface of the interlayer insulation layer 132m. The additional charge storage layer 158 may be formed to a predetermined thickness so as not to completely fill the inside of the recess RC. To this end, an insulating material may be deposited in at least a portion of the recess RC, followed by an etching process to remove a portion of the insulating material located inside the recess RC. In embodiments, the process of re-etching the portion of the insulating material located within the recess RC may be performed by a wet etching process, but is not limited thereto.

Next, a gate insulation layer 157 may be formed on the inner surface of the additional charge storage layer 158 formed inside the recess RC. The gate insulation layer 157 may be formed on the inner surface of the additional charge storage layer 158 formed on the side surface of the sacrificial insulation layer 130s and on a portion of the upper surface and a portion of the lower surface of the interlayer insulation layer 132m. The gate insulation layer 157 may be formed to a predetermined thickness so as not to completely fill the inside of the recess RC.

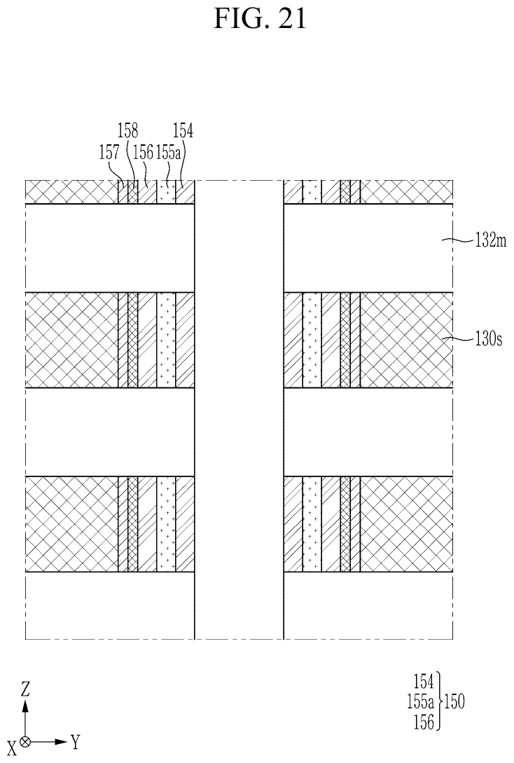

As illustrated in FIG. 21, a multi-layered structures 150 including a first layer 154, a charge storage layer 155a, and a second layer 156 may be formed inside the recess RC. In embodiments, the second layer 156, the charge storage layer 155a and the first layer 154 may be sequentially formed on the inner surface of the additional charge storage layer 158 formed inside the recess RC.

First, a second layer 156 may be formed to fill a portion of the inside of the recess RC. To form the second layer 156 only in a portion of the inside of the recess RC, a ferroelectric material layer (or antiferroelectric material layer) may be deposited in at least some regions of the recess RC and the channel hole CT, and then, by an etch-back process, the entire ferroelectric material layer formed in the channel hole CT and a portion of the ferroelectric material layer formed in the recess RC may be etched. The etch-back process may be performed by a wet etching process, but is not limited thereto.

Next, a charge storage layer 155a that fills a portion of the inside of the recess RC may be formed. The charge storage layer 155a may be formed on the inner surface of the second layer 156 formed inside the recess RC. For this, a process of filling the inside of the recess RC with an insulating material and an etch-back process may be performed, and a detailed description thereof will be omitted.

Next, a first layer 154 may be formed to fill the inside of the recess RC. The first layer 154 may be formed on the inner surface of the charge storage layer 155a formed inside the recess RC. In embodiments, the first layer 154 may be formed to completely fill the inside of the recess RC. After a ferroelectric (or antiferroelectric) material layer is deposited over the entire inner region of the recess RC and at least a portion of the channel hole CT, a remaining portion of the ferroelectric (or antiferroelectric) material layer located inside the channel hole CT, excluding the inside of the recess RC, may be selectively removed through an etch-back process. In the embodiment, the inner surface of the first layer 154 may form a coplanar surface with the inner surface of the interlayer insulation layer 132m.

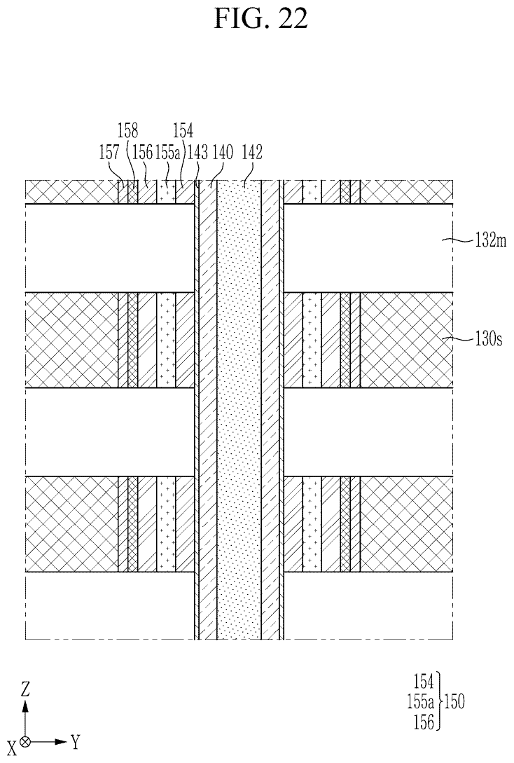

As illustrated in FIG. 22, a channel insulation layer 143 and a channel layer 140 may be formed on the inner surface of the first layer 154. The channel insulation layer 143 and the channel layer 140 may be sequentially stacked on the inner surface of the first layer 154.

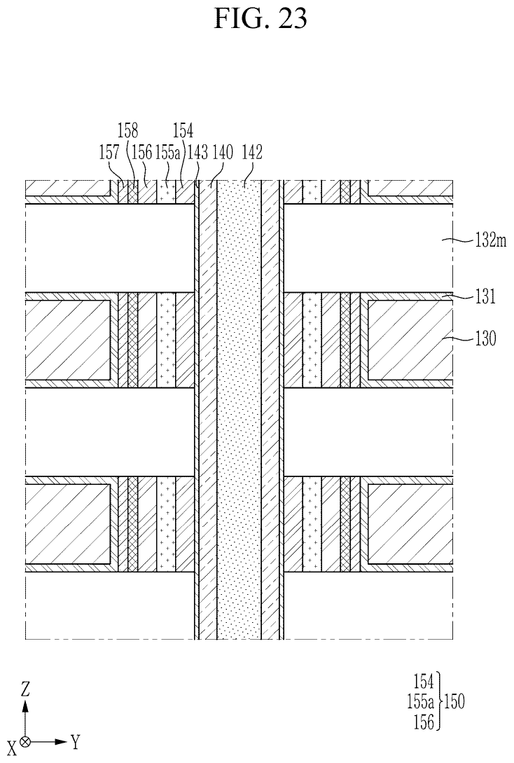

Subsequently, as shown in FIG. 23, a core insulation layers 142 may be formed inside the channel hole CT, and a gate electrode 130 and a barrier layer 131 may be formed in locations corresponding to the sacrificial insulation layers 130s, thereby forming the semiconductor device as illustrated in FIG. 10.

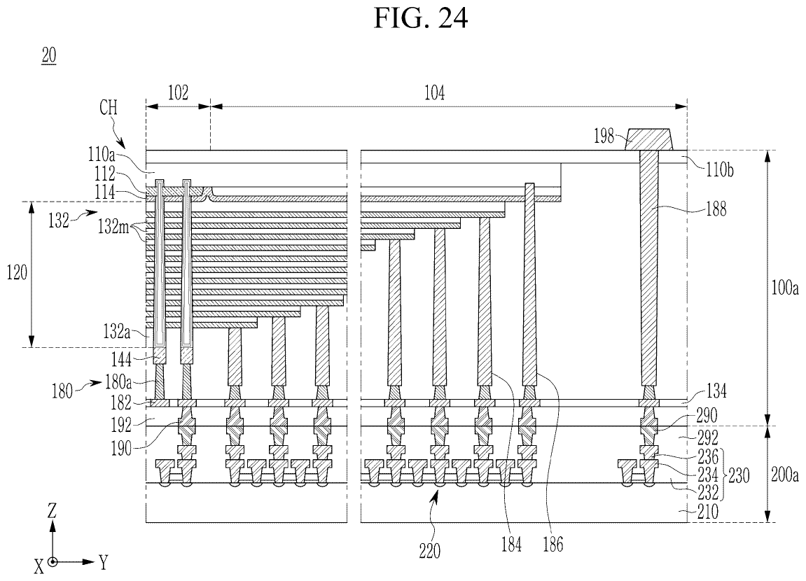

FIG. 24 is a partial cross-sectional view schematically illustrating a semiconductor device according to an additional embodiment.

Referring to FIG. 24, in embodiments, the semiconductor device 20 may be a bonded semiconductor device in which the cell region 100a is separately formed from the circuit region 200a, and subsequently bonded to the circuit region 200a. For example, the cell region 100a may be bonded to the circuit region 200a by a chip-to-chip (C2C) bonding process, a chip-to-wafer bonding process, or a wafer-to-wafer bonding process using a hybrid bonding method.

The circuit region 200a may include a first substrate 210, a circuit element 220, a first wiring portion 230, and a first bonding structure 290 electrically connected to the first wiring portion 230 and positioned on one side surface facing the cell region 100a. A peripheral area of the first bonding structure 290 on one side surface of the circuit region 200a may be covered by a first bonding insulation layer 292.

The cell region 100a may include a second substrate 110a, a gate stack structure 120, a channel structure CH, a second wiring portion 180, and a second bonding structure 190 electrically connected to the second wiring portion 180 and positioned on a surface facing the circuit region 200a. The region other than the portion where the second bonding structure 190 may be located may be covered by the second bonding insulation layer 192.

In the embodiment, the second substrate 110a may be a semiconductor substrate including a semiconductor material. For example, the second substrate 110a may be a semiconductor substrate made of a semiconductor material, or may be a semiconductor substrate in which a semiconductor layer is formed on a base substrate. For example, the second substrate 110a may be composed of single crystal or polycrystalline silicon, germanium, silicon-germanium, silicon-on-insulator, or germanium-on-insulator. Alternatively, the second substrate 110a may include a support member including an insulation layer or insulating material. This is because after the cell region 100a is bonded to the circuit region 200a, the semiconductor substrate provided in the cell region 100a may be removed and a support member including an insulation layer or an insulating material may be formed.

In one embodiment, the gate stack structure 120 may be sequentially stacked below the second substrate 110a in the drawings, and may be disposed in an inverted orientation compared to the gate stack structure 120 shown in FIG. 1. The channel structure CH penetrating the gate stack structure 120 may also have a vertically inverted structure compared to the channel structure CH shown in FIG. 2. Accordingly, the channel structure CH may have an inclined side surface such that its width decreases from the circuit region 200a toward the second substrate 110a in a cross-sectional view. And the channel pad 144 and the second wiring portion 180 on the gate stack structure 120 may be located adjacent to the circuit region 200a.

In the embodiment, the input/output connection wiring 188 may be electrically connected to a portion of the second bonding structures 190. The input/output pad 198 may be located, for example, on an external insulation layer 110b located on the outer surface of the second substrate 110a. In some embodiments, a separate input/output pad electrically connected to the circuit region 200a may also be provided. The semiconductor device according to the embodiment may further include an insulation layer covering a portion of the input/output pad 198.

In FIG. 24, the gate stack structure 120 is exemplified as including one stacked portion, but may alternatively include two or more stacked portions. Unless stated otherwise, the description of the gate stack structure 120 and the channel structure CH with reference to FIG. 1 and FIG. 2 may be equally applicable. In FIG. 24, an example is illustrated in which the electrical connection structure between the channel structure CH and the horizontal conductive layers 112, 114 and/or the second substrate 110a is the same as that in FIG. 1. The embodiment is not limited thereto, and the electrical connection structure between the channel structure CH and the horizontal conductive layers 112, 114 and/or the second substrate 110a may be variously modified.

The circuit region 200a and the cell region 100a may be bonded by hybrid bonding. More specifically, the circuit region 200a and the cell region 100a may be bonded by hybrid bonding, which includes a metal-to-metal bonding between a first bonding structure 290 and a second bonding structure 190, and an insulator-to-insulator bonding between a first bonding insulation layer 292 and a second bonding insulation layer 192.

For example, the first bonding structure 290 and/or the second bonding structure 190 may include at least one of copper, aluminum, tungsten, nickel, gold, tin, manganese, cobalt, titanium, tantalum, ruthenium, and beryllium, or an alloy including the same. For example, the first and second bonding structures 290, 190 may include copper, so that the cell region 100a and the circuit region 200a may be bonded (for example, bonded in direct contact) by copper-to-copper bonding.

For example, the first bonding insulation layer 292 and the second bonding insulation layer 192 may include the same insulating material at their bonding interface. For example, at least at the bonding interface, the first bonding insulation layer 292 and/or the second bonding insulation layer 192 may include a layer comprising silicon carbonitride. However, the examples are not limited thereto. The first bonding insulation layer 292 and/or the second bonding insulation layer 192 may include the same material as the cell insulation layer 132 or a separate insulation layer 134 of the cell region 100a, or the first insulation layer 232 of the circuit region 200a, but is not limited thereto and may include other materials.

In the embodiment, the bit lines 182 connected to the channel structure CH, the gate electrodes 130, the second substrate 110a, and/or the horizontal conductive layers 112, 114 may be electrically connected to the circuit elements 220 of the circuit region 200a through the second wiring portion 180, the second bonding structure 190, the first bonding structure 290, and the first wiring portion 230.

For example, the circuit region 200a and the cell region 100a may be portions corresponding to the first structure 1100F and the second structure 1100S of the semiconductor device 1100 included in the electronic system 1000 illustrated in FIG. 19, respectively. Alternatively, the circuit region 200a and the cell region 100a may be regions including the first structure 4100 and the second structure 4200 of the semiconductor chip 2200 illustrated in FIG. 22, respectively.

Next, an electronic system including a semiconductor device according to embodiments will be described with reference to FIG. 25.

FIG. 25 is a schematic diagram illustrating an electronic system including a semiconductor device according to embodiments.

As illustrated in FIG. 25, an electronic system 1000 according to embodiments may include a semiconductor device 1100 and a controller 1200 electrically connected to the semiconductor device 1100. The electronic system 1000 may be a storage device including one or more semiconductor devices 1100 or an electronic device including a storage device. For example, the electronic system 1000 may be a solid state drive device (SSD), a Universal Serial Bus (USB), a computing system, a medical device, or a communication device including one or more semiconductor devices 1100.

The semiconductor device 1100 may be a nonvolatile memory device, for example, a NAND flash memory device as described with reference to FIG. 1 to FIG. 10. The semiconductor device 1100 may include a first structure 1100F and a second structure 1100S on the first structure 1100F. In an exemplary embodiment, the first structure 1100F may be positioned next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, a word line WL, first and second gate upper lines UL1, UL2, first and second gate lower lines LL1, LL2, and a memory cell string CSTR between the bit line BL and the common source line CSL.

In the second structure 1100S, each of the memory cell strings CSTR may include the lower transistor LT1, LT2 adjacent to the common source line CSL, the upper transistors UT1, UT2 adjacent to the bit line BL, and a plurality of memory cell transistors MCT disposed between the lower transistors LT1, LT2 and the upper transistors UT1, UT2. The number of lower transistors LT1, LT2 and the number of upper transistors UT1, UT2 may vary depending on the embodiment.

In an exemplary embodiment, the lower transistors LT1, LT2 may include ground selection transistors, and the upper transistors UT1, UT2 may include string selection transistors. The first and second gate lower lines LL1, LL2 may be gate electrodes of lower transistors LT1, LT2, respectively. The word line WL may be a gate electrode of the memory cell transistor MCT, and the upper gate lines UL1, UL2 may be gate electrodes of upper transistors UT1, UT2, respectively.

The common source line CSL, the first and second gate lower lines LL1, LL2, the word line WL, and the first and second gate upper lines UL1, UL2 may be electrically connected to the decoder circuit 1110 through a first connecting wire 1115 extending from within the first structure 1100F to the second structure 1100S. The bit line BL may be electrically connected to the page buffer 1120 via a second connecting wire 1125 extending from the first structure 1100F to the second structure 1100S.

In the first structure 1100F, the decoder circuit 1110 and the page buffer 1120 may execute a control operation for at least one memory cell transistor selected from among the plurality of memory cell transistors MCTs. The decoder circuit 1110 and the page buffer 1120 may be controlled by the logic circuit 1130. The semiconductor device 1100 may communicate with the controller 1200 through an input/output pad 1101 that is electrically connected to a logic circuit 1130. The input/output pad 1101 may be electrically connected to the logic circuit 1130 via an input/output connecting wiring 1135 extending from the first structure 1100F to the second structure 1100S.

The controller 1200 may include a processor 1210, a NAND controller 1220, and a host interface 1230. According to embodiments, the electronic system 1000 may include a plurality of semiconductor devices 1100, in which case the controller 1200 may control the plurality of semiconductor devices 1100.

The processor 1210 may control the operation of the overall electronic system 1000 including the controller 1200. The processor 1210 may be configured to operate based on predetermined firmware, and to control the NAND controller 1220 to access the semiconductor device 1100. The NAND controller 1220 may include a NAND interface 1221 for communicating with the semiconductor device 1100. Through the NAND interface 1221, various signals may be transmitted, including control commands for controlling the semiconductor device 1100, data to be written to memory cell transistors MCT of the semiconductor device 1100, and data to be read from the memory cell transistors MCT of the semiconductor device 1100. The host interface 1230 may provide communication functionality between the electronic system 1000 and an external host. When receiving a control command from an external host through the host interface 1230, the processor 1210 may control the semiconductor device 1100 in response to the control command.

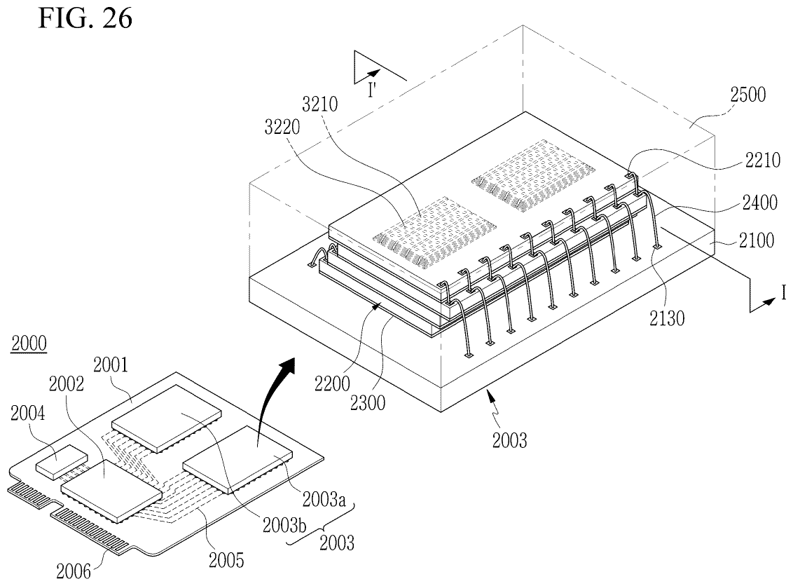

FIG. 26 is a perspective view schematically illustrating an electronic system including a semiconductor device according to embodiments.

As illustrated in FIG. 26, an electronic system 2000 according to embodiments may include a main substrate 2001, a controller 2002 mounted on the main substrate 2001, one or more semiconductor packages 2003, and a DRAM 2004. The semiconductor package 2003 and DRAM 2004 may be connected to the controller 2002 by a wiring pattern 2005 formed on the main substrate 2001.

The main substrate 2001 may include a connector 2006 having a plurality of pins that couple to an external host. The number and arrangement of the plurality of pins in the connector 2006 may vary depending on the communication interface between the electronic system 2000 and the external host. In an exemplary embodiment, the electronic system 2000 may communicate with an external host via any one of interfaces such as USB (Universal Serial Bus), PCI-Express (Peripheral Component Interconnect Express), SATA (Serial Advanced Technology Attachment), or M-Phy for UFS (Universal Flash Storage). In an exemplary embodiment, the electronic system 2000 may operate by power supplied from an external host via the connector 2006. The electronic system 2000 may further include a Power Management Integrated Circuit (PMIC) that distributes power supplied from an external host to the controller 2002 and the semiconductor package 2003.

The controller 2002 may write data to the semiconductor package 2003 or read data from the semiconductor package 2003, and may improve the operating speed of the electronic system 2000.

DRAM 2004 may be a buffer memory to alleviate the speed difference between the semiconductor package 2003, which is a data storage space, and an external host. The DRAM 2004 included in the electronic system 2000 may also function as a type of cache memory and may provide space for temporarily storing data in a control operation for the semiconductor package 2003. When the electronic system 2000 includes a DRAM 2004, the controller 2002 may further include a DRAM controller for controlling the DRAM 2004 in addition to a NAND controller for controlling the semiconductor package 2003.

The semiconductor package 2003 may include first and second semiconductor packages 2003a, 2003b spaced apart from each other. The first and second semiconductor packages 2003a, 2003b may each be semiconductor packages including a plurality of semiconductor chips 2200. Each of the first and second semiconductor packages 2003a, 2003b may include a package substrate 2100, a semiconductor chip 2200 on the package substrate 2100, an adhesive layer 2300 disposed on a lower surface of each of the semiconductor chips 2200, a connecting structure 2400 electrically connecting the semiconductor chip 2200 and the package substrate 2100, and a molding layer 2500 covering the semiconductor chip 2200 and the connecting structure 2400 on the package substrate 2100.

The package substrate 2100 may be a printed circuit board including a package upper pad 2130. Each semiconductor chip 2200 may include an input/output pad 2210. The input/output pad 2210 may correspond to the input/output pad 1101 of FIG. 25. Each semiconductor chip 2200 may include a gate stack structure 3210 and a channel structure 3220. The semiconductor chip 2200 may each include the semiconductor device described with reference to FIG. 1 to FIG. 10.

In an exemplary embodiment, the connecting structure 2400 may be a bonding wire that electrically connects the input/output pad 2210 and the package upper pad 2130. Accordingly, in each of the first and second semiconductor packages 2003a, 2003b, the semiconductor chip 2200 may be electrically connected to each other by a wire bonding method, and may also be electrically connected to package upper pads 2130 of the package substrate 2100. According to embodiments, in each of the first and second semiconductor packages 2003a, 2003b, the semiconductor chips 2200 may be electrically connected to each other by a connection structure including a through silicon via (TSV), instead of the bonding wire-type connecting structure 2400.

In an exemplary embodiment, the controller 2002 and the semiconductor chip 2200 may be included in a single package. For example, a controller 2002 and a semiconductor chip 2200 may be mounted on a separate interposer substrate different from the main substrate 2001, and the controller 2002 and the semiconductor chip 2200 may be connected to each other by wiring formed on the interposer substrate.

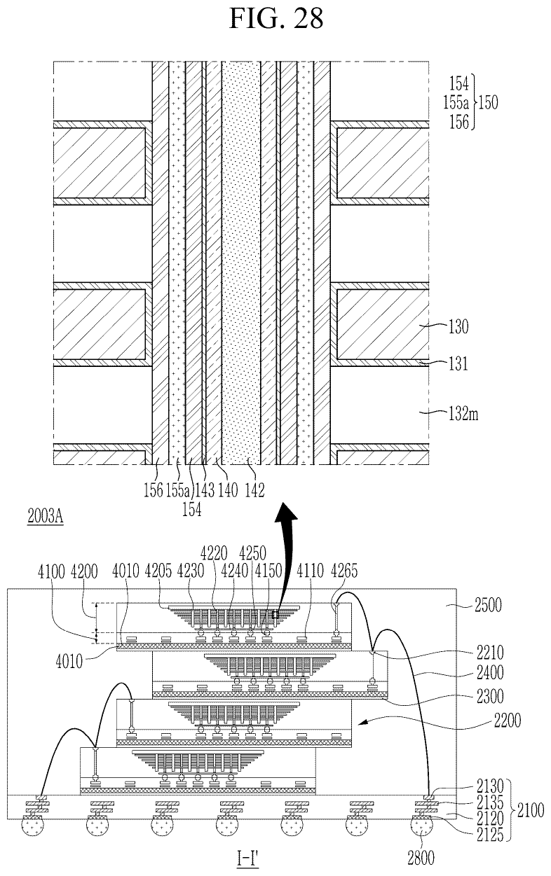

FIG. 27 and FIG. 28 are cross-sectional views schematically illustrating a semiconductor package according to embodiments, respectively. FIG. 27 and FIG. 28 illustrate exemplary embodiments of the semiconductor package 2003 of FIG. 26, respectively, and conceptually represent an area cut along the cutting line II-II′ of the semiconductor package 2003 of FIG. 26.

Referring to FIG. 27, in the semiconductor package 2003, the package substrate 2100 may be a printed circuit board. The package substrate 2100 may include a package substrate body 2120, package upper pads 2130 located on an upper surface of the package substrate body 2120, lower pads 2125 located on or exposed through a lower surface of the package substrate body 2120, and internal wirings 2135 configured to electrically connect the package upper pads 2130 and the lower pads 2125 within the package substrate body 2120. The package upper pad 2130 may be electrically connected to the connecting structure 2400. The lower pad 2125 may be connected to the wiring pattern 2005 of the main substrate 2001 of the electronic system 2000 as shown in FIG. 26 through a conductive connector (2800).

The semiconductor chip 2200 may each include a semiconductor substrate 3010 and a first structure 3100 and a second structure 3200 sequentially stacked on the semiconductor substrate 3010. The first structure 3100 may include a peripheral circuit area including peripheral wiring 3110. The second structure 3200 may include a common source line 3205, a gate stack structure 3210 on the common source line 3205, a channel structure 3220 penetrating the gate stack structure 3210 and a separation structure 3230, a bit line 3240 electrically connected to the channel structure 3220, and a gate connection wiring electrically connected to a word line (see WL of FIG. 25) of the gate stack structure 3210.

A semiconductor chip 2200 or a semiconductor device according to embodiments may include a multi-layered structure 150 located between a gate electrode 130 and a channel structure CH, and the multi-layered structure 150 may include a first layer 154, a second layer 156, and a charge storage layer 155a located between the first layer 154 and the second layer 156. In the embodiment, the first layer 154 and the second layer 156 may include a ferroelectric material or an antiferroelectric material.

The semiconductor device according to the embodiment may store information not only in the first layer 154 and the second layer 156, but also in the charge storage layer 155a, and thus may have a larger memory window compared to a case that does not include the charge storage layer 155a.

In the embodiment, the charge storage layer 155a may be located between the first layer 154 and the second layer 156. In the embodiment, the first layer 154 and the second layer 156 may prevent charges trapped in the charge storage layer 155a from escaping back to the gate electrode 130, thereby improving the retention characteristics of the semiconductor device according to the embodiment.

In the embodiment, when the first layer 154 and the second layer 156 include ferroelectric materials, the amount of charges combining with polarization charges at the interface between the charge storage layer 155a and the first layer 154, or between the charge storage layer 155a and the second layer 156, may be reduced. As a result, depolarization of ramanent polarization in the first layer 154 or the second layer 156 may be reduced, thereby improving the retention characteristics of the semiconductor device.

Each semiconductor chip 2200 may include a through-wiring 3245 that is electrically connected to the peripheral wiring 3110 of the first structure 3100 and extends into the second structure 3200. The through-wiring 3245 extend through the gate stack structure 3210 and may be further positioned outside the gate stack structure 3210. Each semiconductor chip 2200 may further include an input/output connection wiring 3265 electrically connected to the peripheral wiring 3110 of the first structure 3100 and extending into the second structure 3200, and an input/output pad 2210 electrically connected to the input/output connection wiring 3265.

In an exemplary embodiment, a plurality of semiconductor chips 2200 in the semiconductor package 2003 may be electrically connected to each other by the bonding wire-type connecting structure 2400. In another example, the plurality of semiconductor chips 2200, or a plurality of portions constituting the same, may be electrically connected by a connection structure including through-silicon vias (TSVs).

Referring to FIG. 28, in the semiconductor package (2003A), each semiconductor chip 2200 may include a semiconductor substrate (4010), a first structure 4100 on the semiconductor substrate (4010), and a second structure 4200 bonded to the first structure 4100 in a wafer bonding manner on the first structure 4100.

The first structure 4100 may include a peripheral circuit area including peripheral wiring 4110 and a first bonding structure 4150. The second structure 4200 may include a common source line 4205, a gate stack structure 4210 located between the common source line 4205 and the first structure 4100, a channel structure 4220 and a separation structure 4230 penetrating the gate stack structure 4210, and second bonding structures 4250 electrically connected to the word line (WL, see FIG. 25) of the channel structure 4220 and the gate stack structure 4210, respectively. For example, the second bonding structure 4250 may be electrically connected to the channel structure 4220 and the word line WL, respectively, through a bit line 4240 electrically connected to the channel structure 4220 and a gate connection wiring electrically connected to the word line WL. The first bonding structure 4150 of the first structure 4100 and the second bonding structure 4250 of the second structure 4200 may be bonded to each other while being in contact with each other. The bonded portions of the first bonding structure 4150 and the second bonding structure 4250 may be formed of, for example, copper (Cu).

A semiconductor chip 2200 or a semiconductor device according to embodiments may include a multi-layered structure 150 located between a gate electrode 130 and a channel structure CH, and the multi-layered structure 150 may include a first layer 154, a second layer 156, and a charge storage layer 155a located between the first layer 154 and the second layer 156. In embodiments, the first layer 154 and the second layer 156 may include a ferroelectric material or an antiferroelectric material.

The semiconductor device according to the embodiment may store information not only in the first layer 154 and the second layer 156, but also in the charge storage layer 155a, and thus may have a larger memory window compared to a case that does not include the charge storage layer 155a.

In embodiments, the charge storage layer 155a may be located between the first layer 154 and the second layer 156. In the embodiment, the first layer 154 and the second layer 156 may prevent charges trapped in the charge storage layer 155a from escaping back to the gate electrode 130, thereby improving the retention characteristics of the semiconductor device according to the embodiment.

In the embodiment, when the first layer 154 and the second layer 156 include ferroelectric materials, the amount of charges combining with polarization charges at the interface between the charge storage layer 155a and the first layer 154, or between the charge storage layer 155a and the second layer 156, may be reduced. As a result, depolarization of ramanent polarization in the first layer 154 or the second layer 156 may be reduced, thereby improving the retention characteristics of the semiconductor device.

Each semiconductor chip 2200 may further include an input/output pad 2210 and an input/output connection wiring 4265 located below the input/output pad 2210. The input/output connection wiring 4265 may be electrically connected to a portion of the second bonding structure 4250.

In embodiments, a plurality of semiconductor chips 2200 in a semiconductor package 2003 may be electrically connected to each other by a bonding wire-type connecting structure 2400. As another example, a plurality of semiconductor chips 2200 or a plurality of portions constituting the same may be electrically connected by a connecting structure including through-silicon vias.

Although the embodiments have been described in detail above, the scope of the present disclosure is not limited thereto, and various modifications and improvements made by those skilled in the art using the basic concept of the present disclosure defined in the following claims also fall within the scope of the present disclosure.

What is claimed is:

1. A semiconductor device comprising:
a substrate;
a gate stack structure including interlayer insulation layers and gate electrodes alternately stacked on the substrate;
a channel structure including a channel layer extending in a first direction perpendicular to one surface of the substrate and connected to the substrate, the channel structure penetrating the gate stack structure; and
a multi-layered structure extending in the first direction and including a first layer located between the channel layer and the gate electrode, a second layer located between the first layer and the gate electrode, and a third layer located between the first layer and the second layer,
wherein each of the first layer and the second layer includes a ferroelectric material or an antiferroelectric material, and the third layer includes at least one insulation layer.

2. The semiconductor device of claim 1,
wherein the at least one insulation layer includes a charge storage layer and passivation layers located on both side surfaces of the charge storage layer.

3. The semiconductor device of claim 2,
wherein the charge storage layer includes an oxide and the passivation layers include a nitride.

4. The semiconductor device of claim 2, wherein the passivation layer includes at least one of AlN and AlSiON.

5. The semiconductor device of claim 2,
wherein the charge storage layer includes at least one of Al₂O₃, SiO₂, and AlSiO.

6. The semiconductor device of claim 3, wherein a dielectric constant of the oxide included in the charge storage layer is less than or equal to a dielectric constant of the ferroelectric material or the antiferroelectric material included in the first layer and the second layer.

7. The semiconductor device of claim 2,
wherein the charge storage layer and the passivation layers are stacked in a second direction perpendicular to the first direction, and
a thickness of the passivation layers in the second direction is less than or equal to a thickness of the charge storage layer in the second direction.

8. The semiconductor device of claim 7,
wherein a total thickness of the multi-layered structure in the second direction is greater than or equal to 0.3 nm and less than or equal to 20 nm.

9. The semiconductor device of claim 1,
wherein the antiferroelectric material includes a two-dimensional antiferroelectric material or a perovskite material.

10. The semiconductor device of claim 1,
wherein the antiferroelectric material includes at least one of HZO, AgBiP₂Se₆, CuInP₂S₆, CuBiP₂Se₆, In₂Se₃, SnS, BN, graphene, PbZrO₃, PbHfO₃, (Na_{0.5}Bi_{0.5})TiO₃, Pb(Yb_{0.5}Nb_{0.5})O₃, Pb(Lu_{0.5}Nb_{0.5})O₃, Pb(Co_{0.5}W_{0.5})O₃, Pb(Mg_{0.5}W_{0.5})O₃, and Pb(In_{0.5}Nb_{0.5})O_{3.}

11. The semiconductor device of claim 1,
wherein one of the first layer and the second layer includes a ferroelectric material and the other includes an antiferroelectric material.

12. The semiconductor device of claim 2,
wherein the multi-layered structure overlaps the gate electrode in a second direction perpendicular to the first direction and does not overlap the interlayer insulation layer in the second direction.

13. The semiconductor device of claim 1 further comprising,
a gate insulation layer located between the second layer and the gate electrode.

14. The semiconductor device of claim 1 further comprising,
an additional charge storage layer located between the second layer and the gate electrode.

15. The semiconductor device of claim 14,
wherein the additional charge storage layer includes SiNₓ.

16. A semiconductor device comprising:
a substrate;
a gate stack structure including interlayer insulation layers and gate electrodes alternately stacked in a first direction perpendicular to a surface of the substrate;
a channel structure including a core insulation layer extending in the first direction, and a channel layer located between the core insulation layer and the gate electrode and connected to the substrate, the channel structure penetrating the gate structure; and
a multi-layered structure extending in the first direction and including a first layer located between the channel layer and the gate electrode, a second layer located between the first layer and the gate electrode, and a third layer located between the first layer and the second layer,
wherein each of the first layer and the second layer includes a ferroelectric material or an antiferroelectric material, wherein the third layer includes at least one insulation layer, and
wherein the at least one insulation layer includes a charge storage layer containing an oxide and passivation layers containing a nitride and located on inner surface and outer surface of the charge storage layer.

17. The semiconductor device of claim 16,
wherein a dielectric constant of the oxide included in the charge storage layer is less than or equal to a dielectric constant of the ferroelectric material and the antiferroelectric material included in the first layer and the second layer.

18. The semiconductor device of claim 16,
wherein a thickness of the passivation layers in a second direction perpendicular to the first direction is less than or equal to a thickness of the charge storage layer in the second direction.

19. The semiconductor device of claim 16,
wherein the multi-layered structure overlaps the gate electrode in a second direction perpendicular to the first direction and does not overlap the interlayer insulation layer in the second direction.

20. An electronic system comprising:
a main substrate;
a semiconductor device on the main substrate; and
a controller electrically connected to the semiconductor device on the main substrate,
wherein the semiconductor device includes:
a peripheral circuit region,
a cell region including an input/output connection wiring electrically connected to the peripheral circuit region, and
an input/output pad electrically connected to the input/output connection wiring extending into the cell region,
wherein the cell region includes:
a substrate,
a gate stack structure including interlayer insulation layers and gate electrodes alternately stacked on the substrate,
a channel structure including a channel layer extending in a first direction perpendicular to a surface of the substrate and connected to the substrate, the channel structure penetrating the gate stack structure, and
a multi-layered structure extending in the first direction and including a first layer located between the channel layer and the gate electrode, a second layer located between the first layer and the gate electrode, and a third layer located between the first layer and the second layer,
wherein each of the first layer and the second layer includes a ferroelectric material or an antiferroelectric material, and the third layer includes at least one insulation layer.
